(19) United States
(12) Patent Application Publication
(10) Pub. No.: US 2024/0324217 A1
(43) Pub. Date: Sep. 26, 2024

(54) MEMORY DEVICE

(71) Applicant: Kioxia Corporation, Tokyo (JP)

(72) Inventor: Genki KAWAGUCHI, Yokkaichi (JP)

(73) Assignee: Kioxia Corporation, Tokyo (JP)

(21) Appl. No.: 18/599,802

(22) Filed: Mar. 8, 2024

(30) Foreign Application Priority Data
Mar. 23, 2023 (JP) 2023-047226

(51) Int. Cl. H10B 43/27; H01L 21/768; H01L 23/00; H01L 23/522; H01L 25/18; H10B 43/10; H10B 80/00

(52) U.S. Cl. CPC H10B 43/27; H01L 21/76802; H01L 21/76831; H01L 23/5226; H10B 43/10; H01L 24/08; H01L 25/18; H01L 2224/08145; H01L 2924/1431; H01L 2924/14511; H10B 80/00

(57) ABSTRACT

A memory device according to an embodiment includes a substrate, first conductive layers, an insulating layer, pillars, and contacts. The first conductive layers are provided above the substrate. The insulating layer is provided above the first conductive layers. The pillars have portions facing the first conductive layers functioning as memory cells. The contacts are connected to the first conductive layers, respectively. Each of the first conductive layers has, between itself and the substrate, a terrace portion not overlapping with another first conductive layer. Each of the contacts penetrates the insulating layer and is, in a bottom portion thereof, connected to the terrace portion of one first conductive layer among the first conductive layers.

### CROSS-REFERENCE TO RELATED APPLICATIONS

This application is based upon and claims the benefit of priority from Japanese Patent Application No. 2023-047226, filed Mar. 23, 2023, the entire contents of which are incorporated herein by reference.

### FIELD

Embodiments described herein relate generally to a memory device.

### BACKGROUND

A NAND flash memory capable of storing data in a nonvolatile manner is known.

### BRIEF DESCRIPTION OF THE DRAWINGS

FIG. 1 is a block diagram showing an example of an overall configuration of a memory system including a memory device according to a first embodiment.

FIG. 2 is a circuit diagram showing an example of a circuit configuration of a memory cell array included in the memory device according to the first embodiment.

FIG. 3 is a perspective view showing an example of an external appearance of the memory device according to the first embodiment.

FIG. 4 is a plan view showing an example of a planar layout of the memory cell array included in the memory device according to the first embodiment.

FIG. 5 is a cross-sectional view showing an example of a cross-sectional structure including a memory region of the memory device according to the first embodiment.

FIG. 6 is a cross-sectional view taken along line VI-VI of FIG. 5, showing an example of a cross-sectional structure of a memory pillar included in the memory device according to the first embodiment.

FIG. 7 is a cross-sectional view showing an example of a cross-sectional structure including a hookup region of the memory device according to the first embodiment.

FIG. 8 is a cross-sectional view showing an example of a cross-sectional structure including the hookup region of the memory device according to the first embodiment.

FIG. 9 is a schematic diagram showing an outline of a method of manufacturing a memory device having a bonded structure in the first embodiment.

FIG. 10 is a flowchart showing an example of a method of manufacturing the memory device according to the first embodiment.

FIGS. 11 to 19 are cross-sectional views showing examples of cross-sectional structures in the manufacturing process of the memory device according to the first embodiment.

FIGS. 20 to 26 are cross-sectional views showing examples of detailed cross-sectional structures in the formation process of a contact included in the memory device according to the first embodiment.

FIG. 27 is a flowchart showing an example of a method of manufacturing a memory device according to a modification of the first embodiment.

FIGS. 28 to 30 are cross-sectional views showing examples of detailed cross-sectional structures in the formation process of a contact included in a memory device according to a first modification of the first embodiment.

FIGS. 31 to 33 are cross-sectional views showing examples of detailed cross-sectional structures in the formation process of a contact included in a memory device according to a second modification of the first embodiment.

FIGS. 34 and 35 are cross-sectional views showing examples of detailed cross-sectional structures in the formation process of a contact included in a memory device according to a third modification of the first embodiment.

FIG. 36 is a cross-sectional view showing an example of a cross-sectional structure including a hookup region of a memory device according to a second embodiment.

FIG. 37 is a flowchart showing an example of a method of manufacturing the memory device according to the second embodiment.

FIG. 38 is a cross-sectional view showing an example of a cross-sectional structure in the manufacturing process of the memory device according to the second embodiment.

FIGS. 39 to 45 are cross-sectional views showing examples of detailed cross-sectional structures in the formation process of a contact included in the memory device according to the second embodiment.

FIG. 46 is a block diagram showing an example of an overall configuration of a memory system including a memory device according to a third embodiment.

FIG. 47 is a circuit diagram showing an example of a circuit configuration of a memory cell array included in the memory device according to the third embodiment.

FIG. 48 is a perspective view showing an example of an external appearance of the memory device according to the third embodiment.

FIG. 49 is a cross-sectional view showing an example of a cross-sectional structure of the memory device according to the third embodiment.

FIG. 50 is a flowchart showing an example of a method of manufacturing the memory device according to the third embodiment.

FIGS. 51 to 57 are cross-sectional views showing examples of cross-sectional structures in the manufacturing process of the memory device according to the third embodiment.

FIGS. 58 to 64 are cross-sectional views showing examples of detailed cross-sectional structures in the formation process of a contact included in the memory device according to the third embodiment.

FIGS. 65 to 68 are cross-sectional views showing examples of detailed cross-sectional structures in the formation process of a contact included in a memory device according to a first modification of the third embodiment.

FIG. 69 is a flowchart showing an example of a method of manufacturing a memory device according to a second modification of the third embodiment.

FIGS. 70 and 71 are cross-sectional views showing examples of cross-sectional structures in the manufacturing process of the memory device according to the second modification of the third embodiment.

FIG. 72 is a cross-sectional view showing an example of a cross-sectional structure in the manufacturing process of a memory device including a memory pillar of a two-stage structure.

FIG. 73 is a cross-sectional view showing an example of a detailed structure of the vicinity of two bonding pads arranged to face each other.

### DETAILED DESCRIPTION

In general, according to one embodiment, a memory device includes a substrate, a plurality of first conductive layers, an insulating layer, a plurality of pillars, and a plurality of contacts. The plurality of first conductive layers are provided apart from each other in a first direction above the substrate. The insulating layer is provided above the first conductive layers. Each of the plurality of pillars is provided to extend in the first direction. The plurality of pillars have portions facing the first conductive layers and functioning as memory cells. Each of the plurality of contacts is provided to extend in the first direction. The plurality of contacts are connected to the first conductive layers, respectively. Each of the first conductive layers has, between itself and the substrate, a terrace portion not overlapping with another first conductive layer. Each of the contacts penetrates the insulating layer and is, in a bottom portion thereof, connected to the terrace portion of one first conductive layer among the first conductive layers.

Hereinbelow, embodiments are described with reference to the drawings. Each embodiment gives examples of a device and a method for embodying the technical idea of the invention. The drawings are schematic or conceptual ones. The dimensions, ratios, etc. of drawings are not necessarily the same as the actual ones. The illustration of the configuration is omitted as appropriate. The hatching added to the plan view is not necessarily related to the material or characteristics of the component. In the present specification, components having substantially the same function and configuration are marked with the same reference signs. The numerals, characters, etc. added to reference signs are referred to by the same reference signs, and are used to distinguish between similar elements.

### <1> First Embodiment

A memory device 1 according to a first embodiment has a structure (hereinafter, referred to as a bonded structure) in which memory cells are three-dimensionally stacked and a manufacturing method of bonding two semiconductor substrates together is used. In the memory device 1 according to the first embodiment, contacts for stacked wiring lines connected to the stacked memory cells are formed after the two semiconductor substrates are bonded together. Details of the first embodiment will now be described.

### <1-1> Configuration

First, a configuration of the memory device 1 according to the first embodiment is described.

### <1-1-1> Overall Configuration of the Memory Device 1

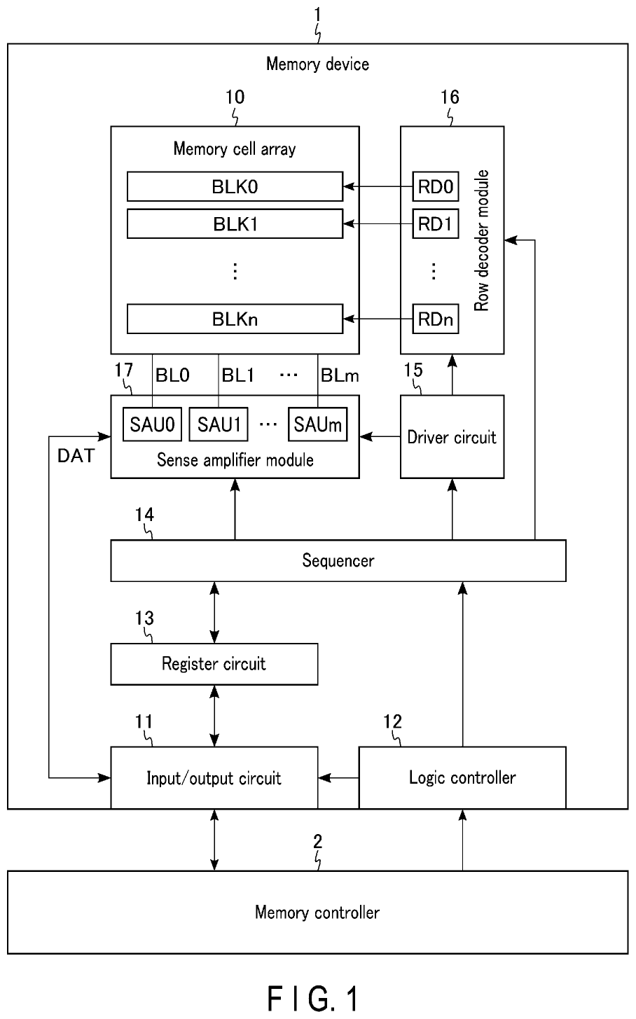

FIG. 1 is a block diagram showing an example of an overall configuration of a memory system including the memory device 1 according to the first embodiment. As shown in FIG. 1, the memory device 1 is controlled by a memory controller 2 in the outside. The memory device 1 is, for example, a NAND flash memory capable of storing data in a nonvolatile manner. The memory device 1 includes, for example, a memory cell array 10, an input/output circuit 11, a logic controller 12, a register circuit 13, a sequencer 14, a driver circuit 15, a row decoder module 16, and a sense amplifier module 17.

The memory cell array 10 includes a plurality of blocks BLK0 to BLKn (“n” is an integer of 1 or more). The block BLK is a set of a plurality of memory cells. The block BLK corresponds to, for example, a unit of data erasure. The block BLK includes a plurality of pages. The page corresponds to a unit in which reading and writing of data are executed. Although illustration is omitted, the memory cell array 10 is provided with a plurality of bit lines BL0 to BLm (“m” is an integer of 1 or more) and a plurality of word lines WL. Each memory cell is associated with, for example, one bit line BL and one word line WL.

The input/output circuit 11 is an interface circuit that takes charge of transmission and reception of input/output signals with the memory controller 2. The input/output signal includes, for example, data DAT, status information, address information, a command, etc. The input/output circuit 11 can input and output data DAT between the sense amplifier module 17 and the memory controller 2. The input/output circuit 11 can output, to the memory controller 2, status information transferred from the register circuit 13. The input/output circuit 11 can output, to the register circuit 13, each of address information and a command transferred from the memory controller 2.

The logic controller 12 controls each of the input/output circuit 11 and the sequencer 14 based on a control signal inputted from the memory controller 2. For example, the logic controller 12 controls the sequencer 14 to enable the memory device 1. The logic controller 12 notifies the input/output circuit 11 that the input/output signal received by the input/output circuit 11 is a command, address information, or the like. The logic controller 12 orders the input/output circuit 11 to input or output an input/output signal.

The register circuit 13 temporarily stores status information, address information, and a command. The status information is updated based on the control of the sequencer 14, and is transferred to the input/output circuit 11. The address information includes a block address, a page address, a column address, and the like. The command includes orders regarding various operations of the memory device 1.

The sequencer 14 controls the entire operation of the memory device 1. The sequencer 14 executes a read operation, a write operation, an erase operation, or the like based on a command and address information stored in the register circuit 13.

The driver circuit 15 generates voltage used in a read operation, a write operation, an erase operation, or the like. Then, the driver circuit 15 supplies the generated voltage to the row decoder module 16, the sense amplifier module 17, or the like.

The row decoder module 16 is a circuit used to select a block BLK to be operated and transfer voltage to a wiring line such as a word line WL. The row decoder module 16 includes a plurality of row decoders RD0 to RDn. The row decoders RD0 to RDn are associated with the blocks BLK0 to BLKn, respectively, and are used to select the block BLK. Each row decoder RD transfers voltage generated by the driver circuit 15 to various wiring lines provided in the memory cell array 10.

The sense amplifier module 17 is a circuit used to transfer voltage to each bit line BL and read data. The sense amplifier module 17 includes a plurality of sense amplifier units SAU0 to SAUm. The sense amplifier units SAU0 to SAUm are associated with the bit lines BL0 to BLm, respectively. Each sense amplifier unit SAU includes a sense amplifier capable of determining data based on the voltage of the associated bit line BL, a latch circuit that temporarily holds data, etc.

A combination of the memory device 1 and the memory controller 2 may constitute one semiconductor device. Examples of such a semiconductor device include a memory card such as an SD™ card, an SSD (solid-state drive), and the like.

### <1-1-2> Circuit Configuration of the Memory Cell Array 10

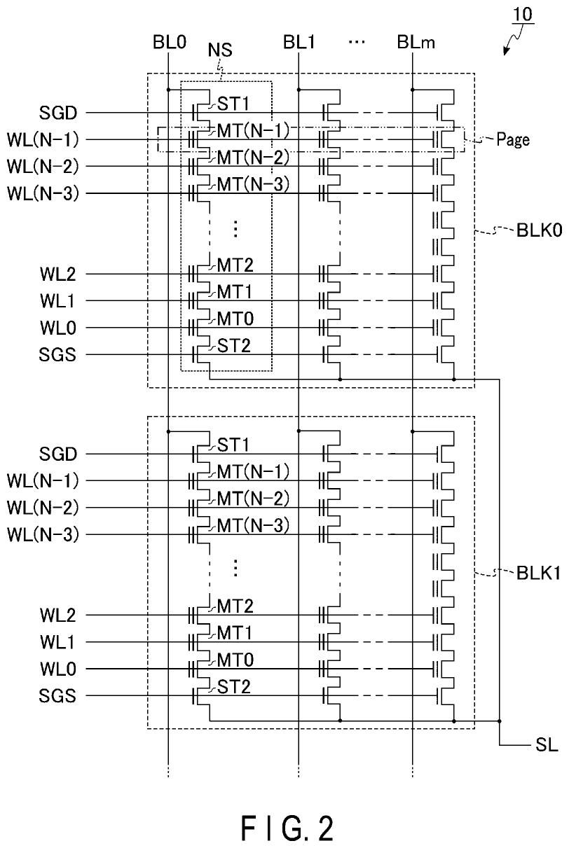

FIG. 2 is a circuit diagram showing an example of a circuit configuration of the memory cell array 10 included in the memory device 1 according to the first embodiment. FIG. 2 shows two blocks BLK0 and BLK1 among the blocks BLK included in the memory cell array 10. As shown in FIG. 2, in the memory cell array 10, select gate lines SGD and SGS and word lines WL0 to WL(N-1) (N is an integer of 2 or more) are provided for each block BLK. Bit lines BL0 to BLm and a source line SL are shared by, for example, a plurality of blocks BLK.

Each block BLK includes a plurality of NAND strings NS. The NAND strings NS are individually associated with the bit lines BL0 to BLm. In other words, each bit line BL is shared by NAND strings NS to which the same column address is allocated among a plurality of blocks BLK. Each NAND string NS is connected between the associated bit line BL and the source line SL. Each NAND string NS includes, for example, N memory cell transistors MT0 to MT(N-1) and select transistors ST1 and ST2. Each memory cell transistor MT is a memory cell including a control gate and a charge storage layer, and holds (stores) data in a nonvolatile manner. Each of the select transistors ST1 and ST2 is used to select the block BLK.

In each NAND string NS, the select transistor ST1, the memory cell transistors MT(N-1) to MT0, and the select transistor ST2 are connected in series in this order. Specifically, the drain end and the source end of the select transistor ST1 are connected to the associated bit line BL and the drain end of the memory cell transistor MT(N-1), respectively. The drain end and the source end of the select transistor ST2 are connected to the source end of the memory cell transistor MT0 and the source line SL, respectively. The memory cell transistors MT0 to MT(N-1) are connected in series between the select transistors ST1 and ST2.

Each select gate line SGD is connected to the gate end of each of the select transistors ST1 included in the associated block BLK. The select gate line SGS is connected to the gate end of each of the select transistors ST2 included in the associated block BLK. The word lines WL0 to WL(N-1) are connected to the control gate ends of the memory cell transistors MT0 to MT(N-1) included in the associated block BLK, respectively. The “page” corresponds to a set of memory cell transistors MT connected to a common word line WL in the same block BLK. The set of memory cell transistors MT connected to a common word line WL in the same block BLK can have a storage capacity of two-page data or more according to the number of bits stored in the memory cell transistors MT.

The circuit configuration of the memory cell array 10 may be another circuit configuration. For example, a plurality of independently controllable select gate lines SGD may be provided in each block BLK. In this case, each block BLK is configured such that selection can be performed in units of a plurality of units individually associated with the select gate lines SGD.

In the following, a case where each NAND string NS includes eight memory cell transistors MT0 to MT7 connected to word lines WL0 to WL7, respectively, is described as an example.

### <1-1-3>Structure of the Memory Device 1

A structure of the memory device 1 according to the first embodiment will now be described. In the drawings referred to below, a three-dimensional orthogonal coordinate system is used. The X direction corresponds to the extending direction of the word line WL. The Y direction corresponds to the extending direction of the bit line BL. The Z direction corresponds to the vertical direction with respect to the front surface of a semiconductor substrate. The “up and down” is defined based on a direction along the Z direction. The positive direction (upward) corresponds to a direction away from the front surface side of a semiconductor substrate taken as a reference. The XY plane (cross section) corresponds to a plane (cross section) parallel to each of the X direction and the Y direction. The YZ cross section corresponds to a cross section parallel to each of the Y direction and the Z direction. The XZ cross section corresponds to a cross section parallel to each of the X direction and the Z direction. The “front surface of a semiconductor substrate” corresponds to a surface on a side on which a semiconductor circuit is formed. The “back surface of a semiconductor substrate” corresponds to a surface on the opposite side to the front surface of the semiconductor substrate.

### (1: External Appearance of the Memory Device 1)

First, an external appearance of the memory device 1 according to the first embodiment is described. The memory device 1 according to the first embodiment is formed by a method in which two semiconductor circuit substrates each with a semiconductor circuit formed thereon are bonded together and the bonded semiconductor circuit substrates are separated on a chip basis. Specifically, the memory device 1 according to the first embodiment has a structure formed by bonding semiconductor substrates SUB1 and SUB2 together. Each of the semiconductor substrates SUB1 and SUB2 is a silicon substrate. In the following, a case where the semiconductor substrate SUB2 is removed in the manufacturing process of the memory device 1 is described. A part of the semiconductor substrate SUB2 may remain after the semiconductor substrates SUB1 and SUB2 are bonded together.

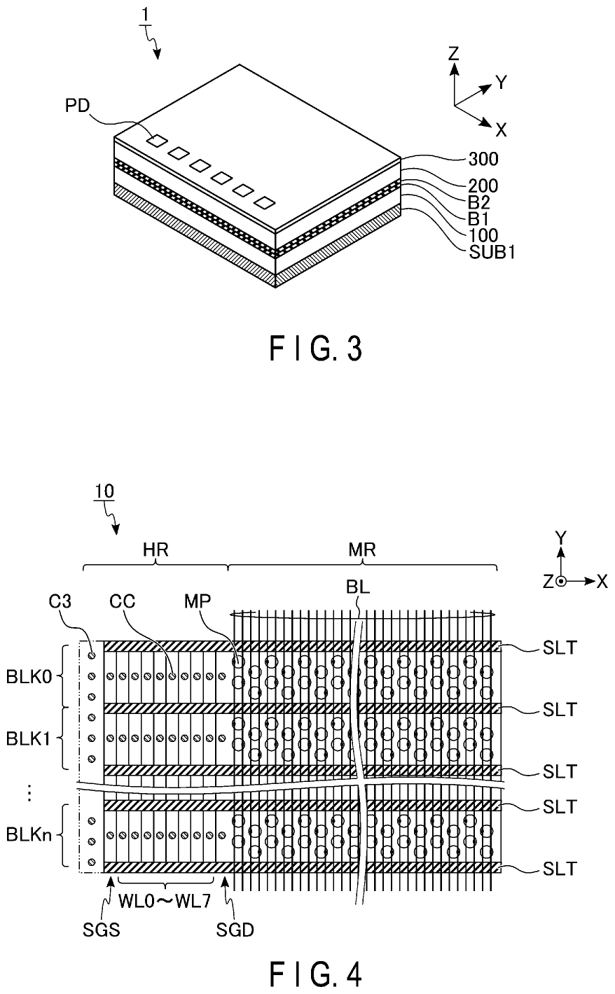

FIG. 3 is a perspective view showing an example of an external appearance of the memory device 1 according to the first embodiment. As shown in FIG. 3, the memory device 1 has a structure in which, for example, the semiconductor substrate SUB1, a CMOS layer 100, a bonding layer B1, a bonding layer B2, a memory layer 200, and a wiring layer 300 are stacked in this order from the bottom.

The CMOS layer 100 includes a CMOS circuit (control circuit) formed using the semiconductor substrate SUB1. The semiconductor substrate SUB1 has an impurity diffusion region, etc. according to the design of the CMOS circuit. The CMOS layer 100 includes, for example, control circuits such as the input/output circuit 11, the logic controller 12, the register circuit 13, the sequencer 14, the driver circuit 15, the row decoder module 16, and the sense amplifier module 17.

The bonding layer B1 is formed using the semiconductor substrate SUB1, and includes a plurality of bonding pads electrically connected to the CMOS circuit provided in the CMOS layer 100 and forming parts of the semiconductor circuit. The bonding layer B2 is formed using the semiconductor substrate SUB2 (not illustrated), and includes a plurality of bonding pads electrically connected to the memory cell array 10 provided in the memory layer 200 and forming parts of the semiconductor circuit. The bonding pads included in the bonding layer B1 are individually connected to a plurality of bonding pads included in the bonding layer B2. A portion between the bonding layers B1 and B2 corresponds to a boundary portion between a layer formed using the semiconductor substrate SUB1 and a layer formed using the semiconductor substrate SUB2 (not illustrated).

The memory layer 200 is formed using the semiconductor substrate SUB2, and includes the memory cell array 10. The wiring layer 300 is formed after the semiconductor substrates SUB1 and SUB2 are bonded together, and includes wiring lines, etc. connected to the semiconductor circuit provided in the memory layer 200. Further, the wiring layer 300 includes a plurality of pads PD. The pads PD are exposed on a surface of the memory device 1. The pads PD are used for connection between the memory device 1 and the memory controller 2, etc.

### (2: Planar Layout of the Memory Cell Array 10)

FIG. 4 is a plan view showing an example of a planar layout of the memory cell array 10 included in the memory device 1 according to the first embodiment. As shown in FIG. 4, the memory cell array 10 includes, for example, a memory region MR and a hookup region HR standing side by side in the X direction. The memory region MR is used to store data. The hookup region HR is used for connection between stacked wiring lines (for example, the word line WL and the select gate lines SGD and SGS) and the row decoder module 16. Further, the memory cell array 10 includes a plurality of slits SLT, a plurality of memory pillars MP, a plurality of contacts CC, and a plurality of contacts C3.

Each slit SLT is a plate-like member provided to extend along the X direction. Each slit SLT has a portion provided to extend along the X direction, and crosses the hookup region HR and the memory region MR along the X direction. The slits SLT stand side by side in the Y direction. Each slit SLT divides wiring lines adjacent via the slit SLT (for example, the word lines WL0 to WL7 and the select gate lines SGD and SGS). In each slit SLT, a conductor provided with a spacer of an insulator on its side wall may be placed to be insulated from these wiring lines, or an insulator may be embedded. In the memory cell array 10, each of the regions partitioned along the Y direction by the slits SLT corresponds to one block BLK.

Each memory pillar MP is, for example, a pillar-like member functioning as one NAND string NS. A plurality of memory pillars MP are arranged in a lattice configuration for each block BLK. At least one bit line BL is placed to overlap with each memory pillar MP. The bit lines BL each have a portion provided to extend in the Y direction, and stand side by side in the X direction. In the present example, two bit lines BL are arranged to overlap with one memory pillar MP. The memory pillar MP and the bit line BL associated with each other are electrically connected to each other via a not-illustrated contact.

Each of the stacked wiring lines (for example, the select gate line SGS, the word lines WL0 to WL7, and the select gate line SGD) included in the memory cell array 10 has a terrace portion in the hookup region HR. The terrace portion corresponds to a portion not overlapping with a wiring line (a conductive layer) on the lower side (the semiconductor substrate SUB1 side) in a top view. The structure formed by the terrace portions is similar to steps, terraces, rimstone, or the like. In the present example, a staircase structure having level differences in the X direction is formed by an end portion of the select gate line SGS, end portions of the word lines WL0 to WL7, and an end portion of the select gate line SGD.

In the hookup region HR, each contact CC is connected to the terrace portion of the associated wiring line among the stacked wiring lines. Specifically, for each block BLK, one contact CC is connected to the terrace portion of each of the select gate line SGS, the word lines WL0 to WL7, and the select gate line SGD. In the hookup region HR, each contact C3 is placed in a region not overlapping with the stacked wiring lines in a top view. Each contact C3 is, for example, electrically connected to the associated contact CC among the contacts CC via a not-illustrated wiring line. The contact C3 may be used for a path that electrically connects the CMOS layer 100 and the wiring layer 300 to each other.

### (3: Cross-Sectional Structure of the Memory Region MR)

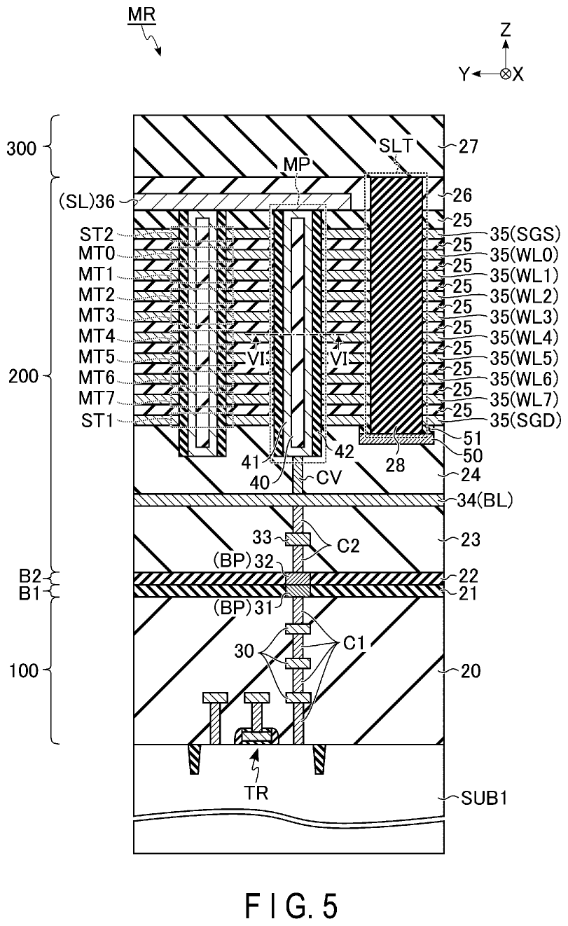

FIG. 5 is a cross-sectional view showing an example of a cross-sectional structure including the memory region MR of the memory device 1 according to the first embodiment. FIG. 5 shows coordinate axes with the semiconductor substrate SUB1 as a reference. As shown in FIG. 5, the memory device 1 according to the first embodiment includes, for example, insulating layers 20 to 27, an insulating member 28, conductive layers 30 to 36, a stopper layer 50, and an insulating layer 51. A transistor TR is provided on the semiconductor substrate SUB1. The transistor TR shown in FIG. 5 corresponds to an element included in the sense amplifier module 17.

Specifically, the CMOS layer 100 includes an insulating layer 20, a plurality of conductive layers 30, and a plurality of contacts C1. The bonding layer B1 includes an insulating layer 21 and a plurality of conductive layers 31. The bonding layer B2 includes an insulating layer 22 and a plurality of conductive layers 32. The memory layer 200 includes insulating layers 23 to 26, a plurality of conductive layers 33 to 36, a plurality of memory pillars MP, an insulating member 28, a plurality of contacts C2 and CV, a stopper layer 50, and an insulating layer 51. The wiring layer 300 includes an insulating layer 27.

The insulating layer 20 is provided on the semiconductor substrate SUB1. In the interior of the insulating layer 20, at least one contact C1 and at least one conductive layer 30 are connected in series on the transistor TR of the memory region MR. The insulating layer 20 may include a plurality of insulating layers.

The insulating layer 21 is provided on the insulating layer 20. The conductive layer 31 is in contact with an upper portion of the uppermost contact C1 indirectly connected to the transistor TR. The conductive layer 31 corresponds to a bonding pad BP formed using the semiconductor substrate SUB1.

The insulating layer 22 is provided on the insulating layer 21. The conductive layer 32 is provided on the conductive layer 31. The conductive layer 32 corresponds to a bonding pad BP formed using the semiconductor substrate SUB2.

The insulating layer 23 is provided on the insulating layer 22. In the interior of the insulating layer 23, at least one contact C2 and at least one conductive layer 33 are connected in series on the conductive layer 32.

The conductive layer 34 is in contact with an upper portion of the uppermost contact C2. The conductive layer 34 has a portion provided to extend in the Y direction, and is used as the bit line BL. Although illustration is omitted, a plurality of conductive layers 34 stand side by side in the X direction. The conductive layer 34 contains, for example, copper.

The insulating layer 24 is provided above the insulating layer 23. The insulating layer 24 covers an upper portion of the conductive layer 34. A conductive layer 35 and an insulating layer 25 are alternately stacked on the insulating layer 24. In other words, a plurality of conductive layers 35 are provided apart from each other in the Z direction. An insulating layer 25 is provided between adjacent conductive layers 35, and an insulating layer 25 is provided on the uppermost conductive layer 35. Each conductive layer 35 is, for example, provided in a plate shape spreading along the XY plane. In the present example, the stacked ten conductive layers 35 are used as the select gate line SGD, the word lines WL7 to WL0, and the select gate line SGS in this order from the conductive layer 34 side. The conductive layer 35 contains, for example, tungsten.

The conductive layer 36 is provided on the uppermost insulating layer 25. The conductive layer 36 is, for example, provided in a plate shape spreading along the XY plane. In the present example, the conductive layer 36 is used as the source line SL. Further, the insulating layer 26 is provided above the uppermost insulating layer 25. The insulating layer 26 covers an upper portion of the conductive layer 36.

Each memory pillar MP has a shape provided to extend in the Z direction. Each memory pillar MP penetrates the insulating layers 25 and the conductive layers 35. That is, each memory pillar MP crosses each of the conductive layers 35. In other words, each memory pillar MP has a portion facing each of the insulating layers 25 and the conductive layers 35 in the XY plane. A portion where the memory pillar MP and the select gate line SGD face each other functions as a select transistor ST1. A portion where the memory pillar MP and the word line WL face each other functions as one memory cell transistor MT. A portion where the memory pillar MP and the select gate line SGS face each other functions as a select transistor ST2. Each memory pillar MP includes a core member 40, a semiconductor layer 41, and a stacked film 42. The core member 40 is provided to extend along the Z direction. The semiconductor layer 41 covers the periphery of the core member 40. An upper portion of the semiconductor layer 41 is in contact with the conductive layer 36 (the source line SL). The stacked film 42 covers the side surface of the semiconductor layer 41. The core member 40 contains an insulator such as silicon oxide. The semiconductor layer 41 contains, for example, silicon. The conductive layer 34 (the bit line BL) and the semiconductor layer 41 (the memory pillar MP) associated with each other are connected to each other via a contact CV.

The insulating layer 27 is provided on the insulating layer 26. The insulating layer 27 includes wiring lines, etc. for connecting the memory cell array 10 and the row decoder module 16 (not illustrated).

The insulating member 28 has, for example, a portion provided along the XZ plane. The insulating member 28 divides the insulating layer 26, the insulating layers 25, and the conductive layers 35 (that is, the stacked wiring lines). The insulating member 28 contains, for example, an insulator such as silicon oxide. The insulating member 28 corresponds to the slit SLT. A stopper layer 50 is provided on a bottom portion of the insulating member 28. The stopper layer 50 is, for example, provided in a layer between the stacked wiring lines and the conductive layer 34. The insulating layer 51 is provided between the stopper layer 50 and the lowermost conductive layer 35. The insulating layer 51 separates and insulates the stopper layer 50 and the lowermost conductive layer 35 from each other. The stopper layer 50 is, for example, polysilicon.

### (4: Cross-Sectional Structure of the Memory Pillar MP)

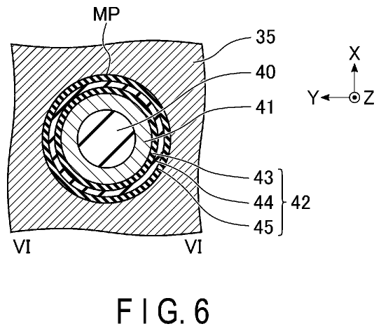

FIG. 6 is a cross-sectional view taken along line VI-VI of FIG. 5, showing an example of a cross-sectional structure of the memory pillar MP included in the memory device 1 according to the first embodiment. FIG. 6 shows a cross-sectional structure of the memory pillar MP in an XY cross section including the conductive layer 35. As shown in FIG. 6, the stacked film 42 includes, for example, a tunnel insulating film 43, an insulating film 44, and a block insulating film 45.

In the cross section including the conductive layer 35, the core member 40 is provided in a central portion of the memory pillar MP. The semiconductor layer 41 surrounds the side surface of the core member 40. The tunnel insulating film 43 surrounds the side surface of the semiconductor layer 41. The insulating film 44 surrounds the side surface of the tunnel insulating film 43. The block insulating film 45 surrounds the side surface of the insulating film 44. The conductive layer 35 surrounds the side surface of the block insulating film 45. Each of the tunnel insulating film 43 and the block insulating film 45 contains, for example, silicon oxide. The insulating film 44 contains, for example, silicon nitride.

In each memory pillar MP described above, the semiconductor layer 41 is used as channels (current paths) of the memory cell transistors MT0 to MT7 and the select transistors ST1 and ST2. The insulating film 44 is used as a charge storage layer of the memory cell transistor MT. The memory device 1 allows a current via the memory pillar MP to flow between the bit line BL and the source line SL by turning on the memory cell transistors MT0 to MT7 and the select transistors ST1 and ST2.

### (5: Cross-Sectional Structure of the Hookup Region HR)

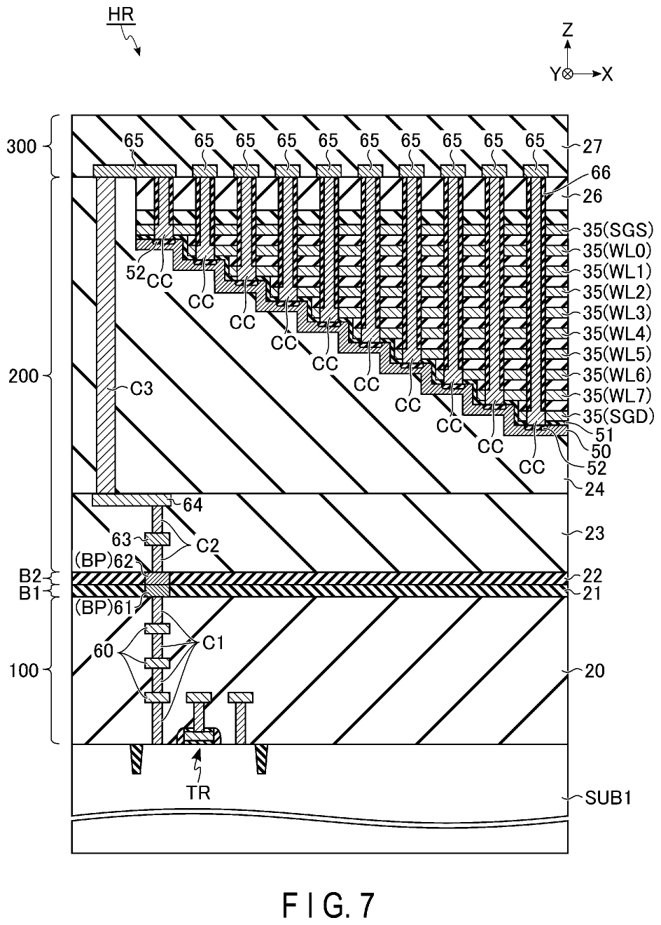

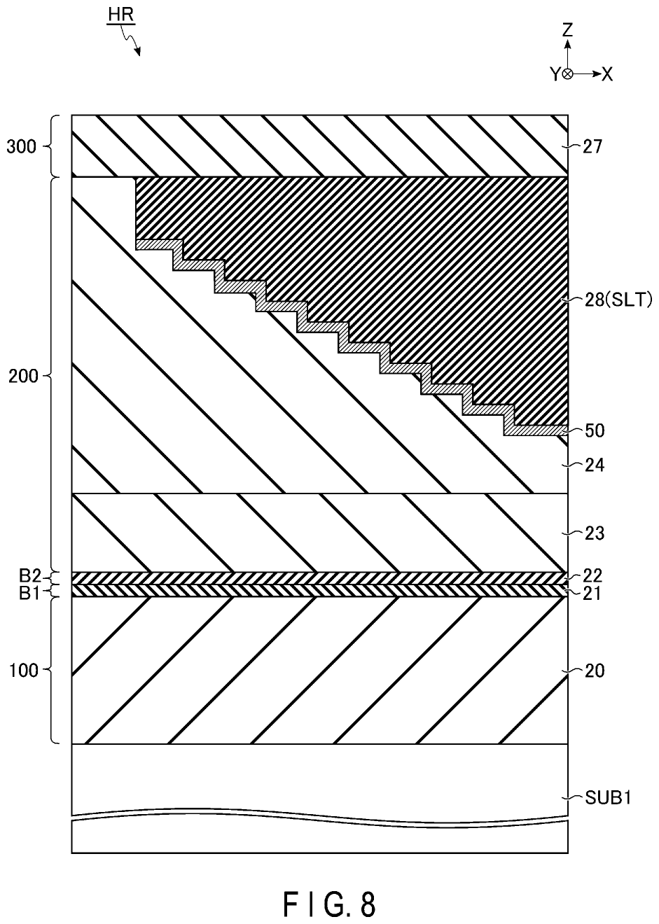

Each of FIGS. 7 and 8 is a cross-sectional view showing an example of a cross-sectional structure including the hookup region HR of the memory device 1 according to the first embodiment. Each of FIGS. 7 and 8 shows coordinate axes with the semiconductor substrate SUB1 as a reference. FIG. 7 shows a cross-sectional structure of the memory device 1 in an XZ cross section including the staircase structure of the stacked wiring lines and a plurality of contacts CC. FIG. 8 shows a cross-sectional structure of the memory device 1 in an XZ cross section including the insulating member 28 dividing the stacked wiring lines. The transistor TR shown in FIG. 7 corresponds to an element included in the row decoder module 16.

As shown in FIG. 7, the memory device 1 according to the first embodiment further includes, for example, conductive layers 60 to 65 and insulating films 66. Specifically, in the hookup region HR, the CMOS layer 100 includes a plurality of conductive layers 60 and a plurality of contacts C1. The bonding layer B1 includes a conductive layer 61. The bonding layer B2 includes a conductive layer 62. The memory layer 200 includes a plurality of conductive layers 63 and 64, a plurality of contacts C2, C3, and CC, and insulating films 66. The wiring layer 300 includes conductive layers 65.

At least one contact C1 and at least one conductive layer 60 are connected in series on the transistor TR of the hookup region HR. The conductive layer 61 is in contact with an upper portion of the uppermost contact C1 indirectly connected to the transistor TR. The conductive layer 61 corresponds to a bonding pad BP formed using the semiconductor substrate SUB1. The conductive layer 62 is provided on the conductive layer 61. The conductive layer 62 corresponds to a bonding pad BP formed using the semiconductor substrate SUB2. At least one contact C2 and at least one conductive layer 63 are connected in series on the conductive layer 62. The conductive layer 64 is in contact with an upper portion of the uppermost contact C2. The height at which the conductive layer 63 is provided is, for example, the same as the height at which the conductive layer 33 is provided. The height at which the conductive layer 64 is provided is, for example, the same as the height at which the conductive layer 34 is provided.

In the hookup region HR, end portions of the conductive layers 35 (the stacked wiring lines) are provided in a staircase shape as described above. In other words, the conductive layers 35 (the stacked wiring lines) have a staircase structure in the hookup region HR. In the hookup region HR, each conductive layer 35 has a portion (terrace portion) not overlapping with a conductive layer 35 provided below. In other words, each conductive layer 35 has, between itself and the semiconductor substrate SUB1, a portion (terrace portion) not overlapping with another conductive layer 35. The bottom surface of the terrace portion of each of the conductive layers 35 (the stacked wiring lines) is covered with a stopper layer 50 provided continuously. The stopper layer 50 and the terrace portion of each of the conductive layers 35 (the stacked wiring lines) are separated and insulated from each other via the insulating layer 51. The stopper layer 50 has a portion (staircase portion) provided in a staircase shape along the staircase structure of the stacked wiring lines. The stopper layer 50 has a portion facing the terrace portion of each of the conductive layers 35 in the Z direction.

The contact C3 is provided on the conductive layer 64. The contact C3 penetrates the insulating layer 24. A conductive layer 65 is in contact with an upper portion of the contact C3. A plurality of conductive layers 65 are provided corresponding to the contacts CC. In other words, the associated conductive layer 65 is provided on each contact CC.

The contacts CC are individually connected to the conductive layers 35. Each contact CC connects the associated conductive layers 35 and 65 to each other. Specifically, each contact CC has a shape that penetrates at least one insulating layer 25 and the insulating layer 26 and extends in the Z direction. The insulating film 66 covers the side surface of the contact CC except for a bottom portion of the contact CC. Each contact CC and the conductive layers 35 other than the associated conductive layer 35 are separated and insulated from each other by the insulating film 66.

The bottom portion of each contact CC is connected to the terrace portion of the associated conductive layer 35. Specifically, the side surface of each contact CC has a discontinuously provided portion in the bottom portion. The side surface of the bottom portion of the contact CC is aligned with the side surface of the insulating film 66. The side surface of the bottom portion of the contact CC is in contact with the associated conductive layer 35. In other words, each contact CC has a first portion including a bottom portion and a second portion of which the side surface is, on the first portion, surrounded by the insulating film 66. In each contact CC, the side surface of the first portion and the side surface of the insulating film 66 are aligned, the first portion has a portion facing the connected conductive layer 35 in a direction (for example, the Y direction) parallel to the surface of the semiconductor substrate SUB1, and each contact CC and the stopper layer 50 are separated and insulated from each other by a set of the insulating layer 51 and an oxide film 52. The oxide film 52 corresponds to, for example, a portion where a part of the stopper layer 50 is oxidized.

As above, the conductive layers 35 are connected to a CMOS circuit (for example, the transistor TR) on the semiconductor substrate SUB1 via a plurality of contacts CC provided corresponding to the conductive layers 35, a plurality of contacts C3 (not illustrated) provided corresponding to the conductive layers 35, a plurality of conductive layers 65 provided on the corresponding contacts CC and C3 and connecting the corresponding sets of contacts CC and C3, two bonding pads BP arranged to face each other between the bonding layers B1 and B2, etc.

As shown in FIG. 8, in an XZ cross section including the insulating member 28, the stopper layer 50 has, like in the XZ cross section including a plurality of contacts CC shown in FIG. 7, a portion (staircase portion) provided along the staircase structure of the stacked wiring lines. In the hookup region HR, the insulating member 28 has a portion provided in a staircase shape along the staircase portion of the stopper layer 50. In other words, the insulating member 28 has a portion provided in a staircase shape along the terrace portions of the conductive layers 35. In the XZ cross section including the insulating member 28, the insulating layer 51 is removed in the formation process of the slit SLT described later. Therefore, a bottom portion of the insulating member 28 is in contact with the staircase portion of the stopper layer 50.

### <1-2> Manufacturing Method

Next, a method of manufacturing the memory device 1 according to the first embodiment is described.

### <1-2-1> Outline of a Method of Manufacturing a Memory Device 1 Having a Bonded Structure

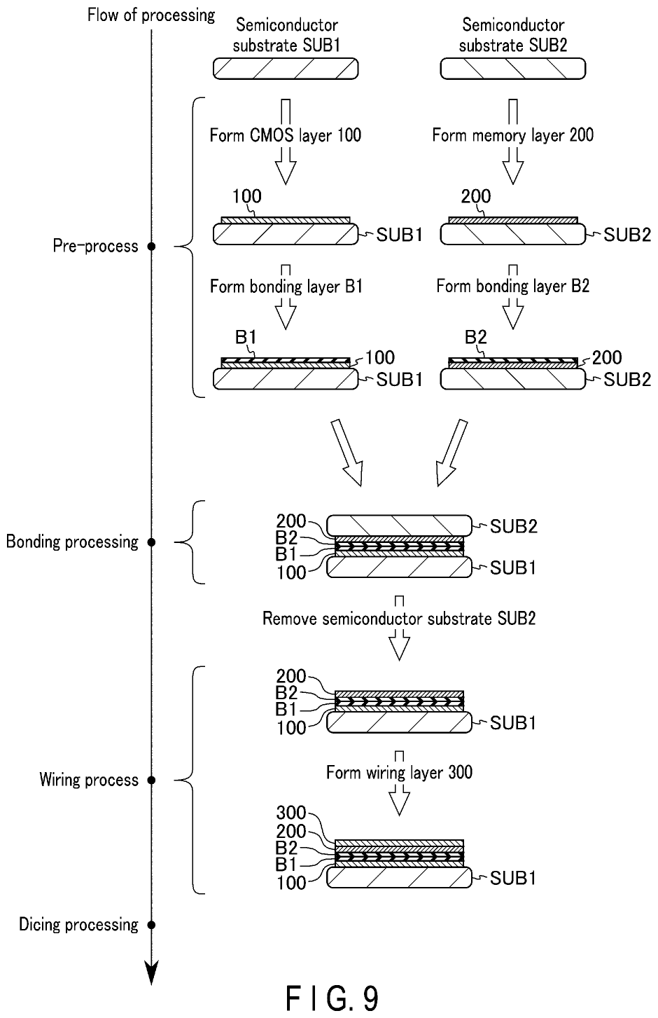

FIG. 9 is a schematic diagram showing an outline of a method of manufacturing a memory device 1 having a bonded structure in the first embodiment. As shown in FIG. 9, in the manufacturing process of the memory device 1, first, a combination of a semiconductor substrate SUB1 and a semiconductor substrate SUB2 is prepared. Next, a pre-process of each of the semiconductor substrates SUB1 and SUB2 is executed, and a semiconductor circuit is formed on each of the semiconductor substrates SUB1 and SUB2. Specifically, a CMOS layer 100 is formed on the semiconductor substrate SUB1. A bonding layer B1 is formed on the CMOS layer 100. Further, a memory layer 200 is formed on the semiconductor substrate SUB2. A bonding layer B2 is formed on the memory layer 200.

Next, bonding processing of the semiconductor substrates SUB1 and SUB2 is executed. In the bonding processing, the front surface of the semiconductor substrate SUB1 and the front surface of the semiconductor substrate SUB2 are arranged to face each other. Then, positions where the pattern formed on the front surface of the semiconductor substrate SUB1 and the pattern formed on the front surface of the semiconductor substrate SUB2 are to be superimposed with each other are adjusted, and the semiconductor substrate SUB1 and the semiconductor substrate SUB2 are bonded together. Specifically, the bonding layer B1 formed on the semiconductor substrate SUB1 and the bonding layer B2 formed on the semiconductor substrate SUB2 are bonded together. At this time, a set of two bonding pads BP arranged to face each other between the bonding layers B1 and B2 come into contact with each other. As a result, the semiconductor circuit provided on the semiconductor substrate SUB1 and the semiconductor circuit provided on the semiconductor substrate SUB2 are electrically connected to each other.

Next, out of the bonded semiconductor substrates SUB1 and SUB2, the semiconductor substrate SUB2 is removed. The semiconductor substrate SUB2 may be removed by back grinding processing or the like, or may be peeled off such that the memory layer 200 remains on the semiconductor substrate SUB1 side. After that, a wiring process is executed using the semiconductor substrate SUB1. Specifically, a wiring layer 300 is formed on the memory layer 200. The wiring process includes a process of forming wiring lines and contacts connected to circuits provided in the CMOS layer 100 and the memory layer 200, a process of forming pads PD, etc. After the wiring process is completed, the semiconductor substrate SUB1 is separated in units of chips by dicing processing. Thereby, a memory device 1 having a bonded structure is formed.

Although the first embodiment shows, as an example, a case where a semiconductor device is formed using two semiconductor substrates SUB1 and SUB2, the present invention is not limited thereto. The number of semiconductor substrates SUB used to form the memory device 1 may be three or more. That is, the memory device 1 may have a bonded structure using three or more semiconductor substrates SUB in total.

### <1-2-2> Method of Forming the Stacked Wiring Lines and the Contact CC

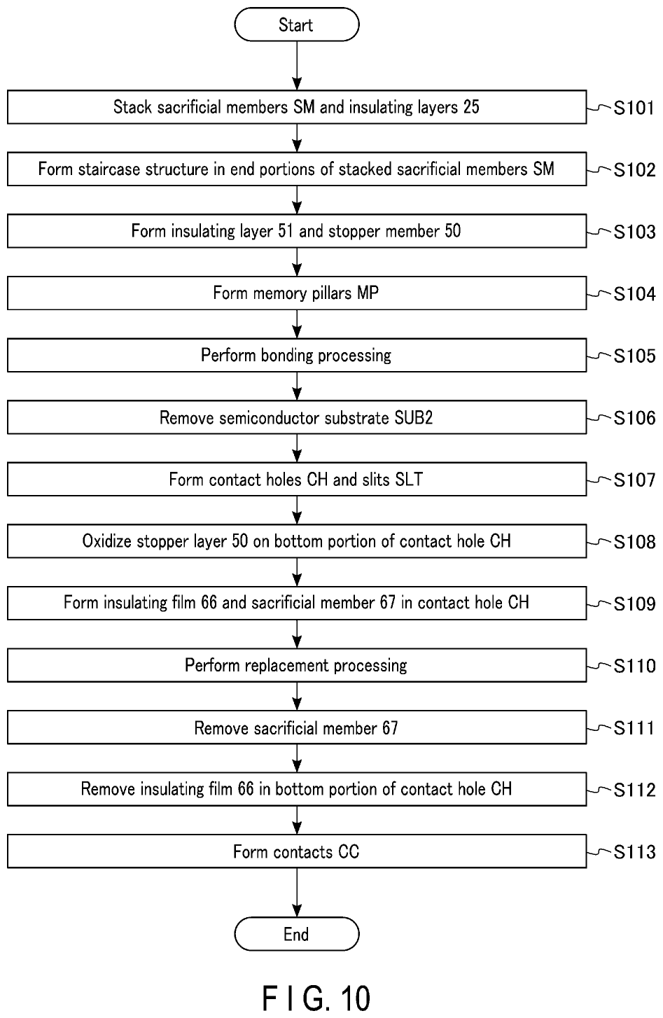

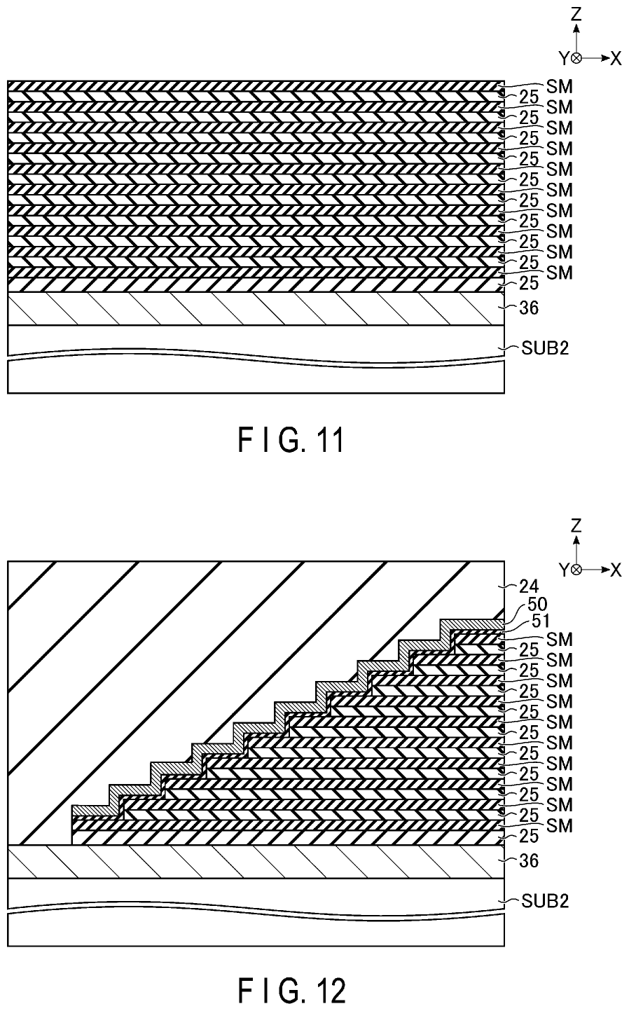

FIG. 10 is a flowchart showing an example of a method of manufacturing the memory device 1 according to the first embodiment. Each of FIGS. 11 to 19 is a cross-sectional view showing an example of a cross-sectional structure in the manufacturing process of the memory device 1 according to the first embodiment, and shows a region corresponding to the hookup region HR. A method of forming the stacked wiring lines and the contact CC included in the memory device 1 according to the first embodiment will now be described with reference to FIG. 10 as appropriate.

First, as shown in FIG. 11, a sacrificial member SM and an insulating layer 25 are alternately stacked (step S101). Specifically, a conductive layer 36 is formed on a semiconductor substrate SUB2, and an insulating layer 25 and a sacrificial member SM are alternately stacked on the conductive layer 36. The number of sacrificial members SM stacked corresponds to the number of stacked wiring lines. The sacrificial member SM is, for example, silicon nitride (SiN).

Next, a staircase structure is formed in end portions of the stacked sacrificial members SM (step S102). In the processing of S102, for example, a set of photolithography processing and etching processing is used.

Next, as shown in FIG. 12, an insulating layer 51 and a stopper layer 50 are formed (step S103). Specifically, an insulating layer 51 and a stopper layer 50 are sequentially formed. Then, by a set of photolithography processing and etching processing, a set of the insulating layer 51 and the stopper layer 50 is processed to remain in a desired region. After that, an insulating layer 24 is formed to fill the level difference portion formed by the stacked structure of sacrificial members SM and insulating layers 25. Then, the upper surface of the insulating layer 24 is planarized.

Next, memory pillars MP are formed in a not-illustrated region (step S104). In the processing of step S104, memory holes penetrating the stacked sacrificial members SM and insulating layers 25 are formed by a set of photolithography processing and etching processing. Then, a stacked film 42, a semiconductor layer 41, and a core member 40 are formed in the memory hole. After that, conductive layers 32 to 34 and 62 to 64, contacts CV and C2, etc. are formed.

Next, bonding processing is executed (step S105). By the processing of step S105, the bonding layer B1 of the semiconductor substrate SUB1 on which the CMOS layer 100 is formed and the bonding layer B2 of the semiconductor substrate SUB2 on which the memory layer 200 is formed are bonded together.

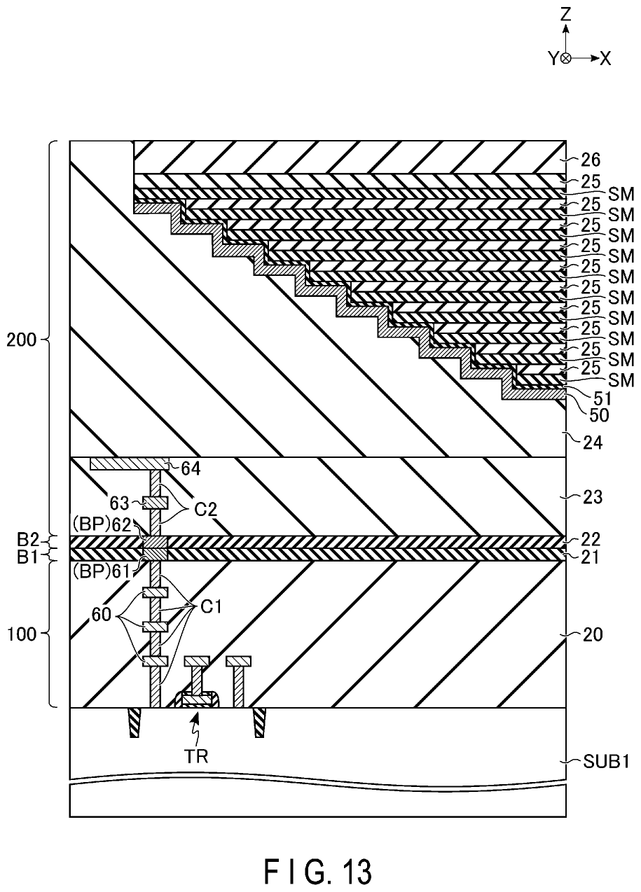

Next, the semiconductor substrate SUB2 is removed (step S106). After that, the conductive layer 36 is processed into a desired shape, and an insulating layer 26 is formed to cover the conductive layer 36. As a result, a structure like that shown in FIG. 13 is formed in the hookup region HR.

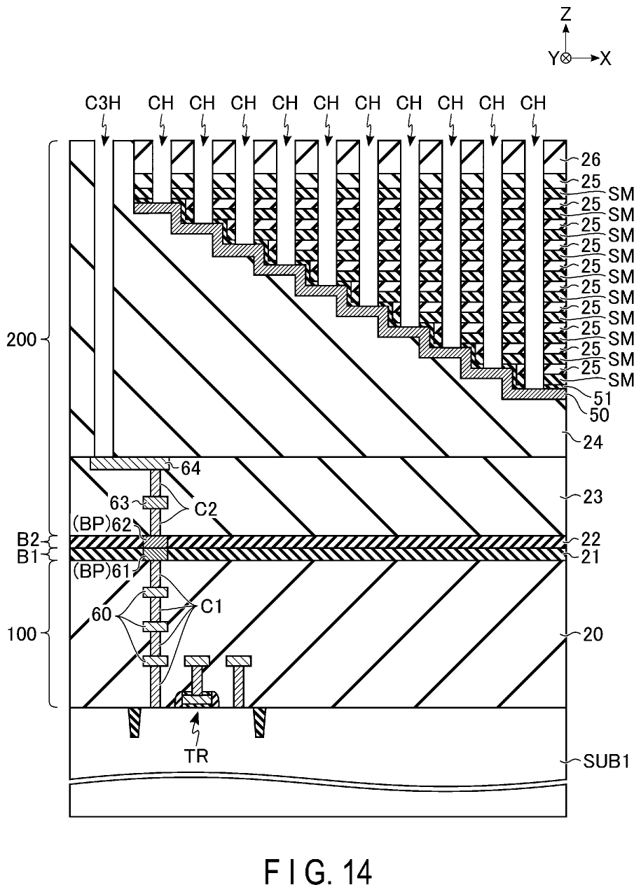

Next, contact holes CH and slits SLT are formed (step S107). In the processing of step S107, etching processing using the stopper layer 50 as an etching stopper is executed. Specifically, as shown in FIG. 14, a plurality of contact holes CH are individually formed in regions corresponding to a plurality of contacts CC. Each contact hole CH is provided to penetrate the insulating layers 25, 26, and 51 and at least one sacrificial member SM. A part of the stopper layer 50 is exposed in a bottom portion of each contact hole CH. In the processing of step S107, contact holes C3H may be simultaneously formed. The contact hole C3H is formed in a region corresponding to a contact C3. The contact hole C3H is provided to penetrate the insulating layer 24. The conductive layer 64 is exposed in a bottom portion of the contact hole C3H. That is, the conductive layer 64 is used as an etching stopper in the formation of the contact hole C3H. The material is not limited thereto, and a similar material to the stopper layer 50 may be used in the formation of the contact hole C3H.

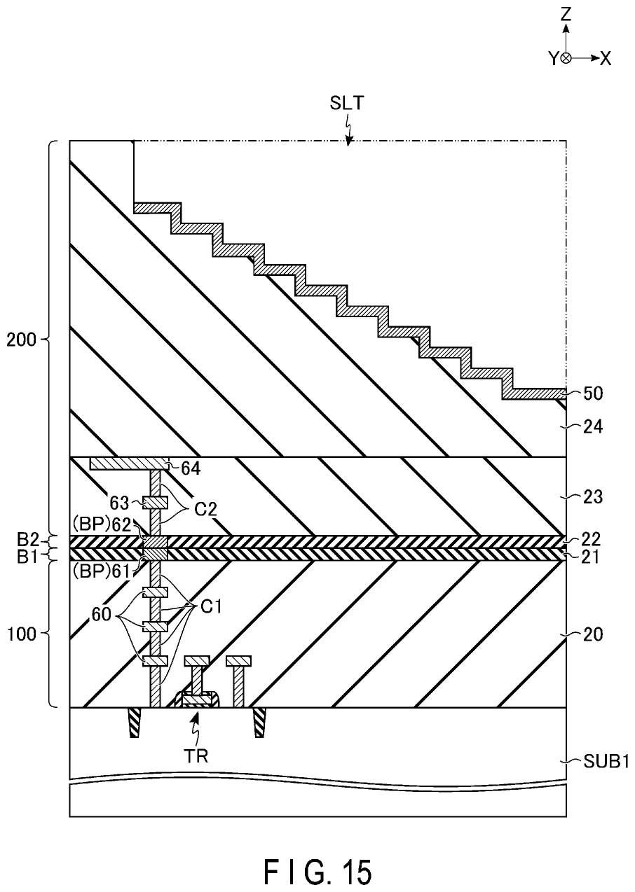

By the processing of step S107, the slit SLT is provided to divide the stacked sacrificial members SM and insulating layers 25 on a block BLK basis. As shown in FIG. 15, the stopper layer 50 in a staircase shape is exposed in a bottom portion of the slit SLT in the hookup region HR. A sacrificial member is embedded in the slit SLT formed by the processing of step S107 until, for example, replacement processing described later is executed.

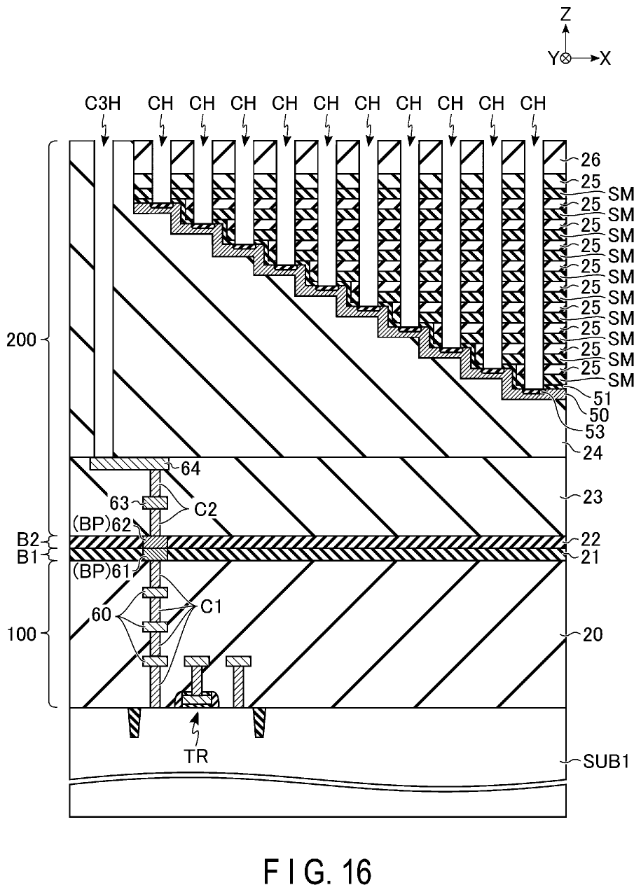

Next, polysilicon of the stopper layer 50 on a bottom portion of the contact hole CH is oxidized (step S108). Specifically, in the processing of step S108, by oxidation processing via the contact hole CH, an oxide film 53 is formed in a portion of the stopper layer 50 exposed in the contact hole CH, as shown in FIG. 16. The oxide film 53 is formed such that at least the contact hole CH and the stopper layer 50 are apart from each other.

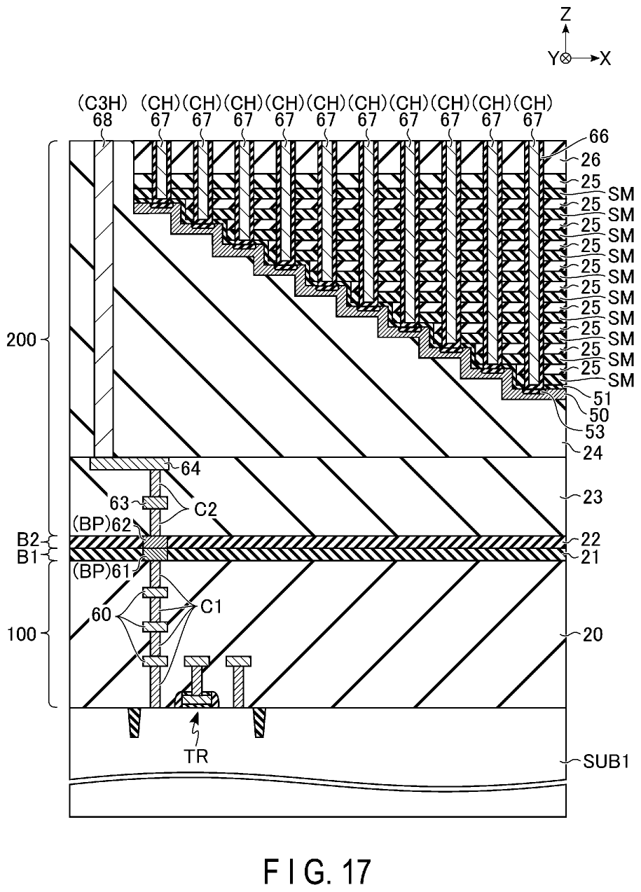

Next, as shown in FIG. 17, an insulating film 66 and a sacrificial member 67 are formed in the contact hole CH (step S109). Specifically, an insulating film 66 and a sacrificial member 67 are sequentially formed. Then, the insulating film 66 and the sacrificial member 67 formed outside the contact hole CH are removed. In the present example, a sacrificial member 68 is formed in the contact hole C3H. The sacrificial member 68 may be formed in a process different from that of the sacrificial member 67, or may be formed simultaneously with the sacrificial member 67. Like in the contact hole CH, an insulating film 66 and a sacrificial member 67 may be formed in the contact hole C3H.

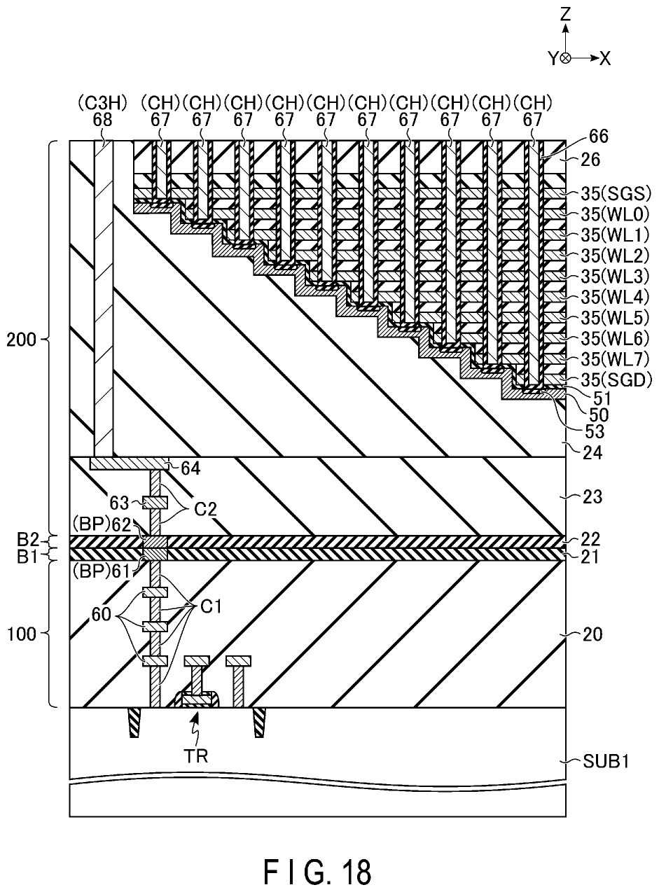

Next, replacement processing is executed (step S110). Specifically, in a case where a sacrificial member is embedded in the slit SLT, the sacrificial member is removed. Then, the sacrificial member SM is removed via the slit SLT by, for example, wet etching using hot phosphoric acid or the like. Then, a conductive layer 35 is embedded in the portion where the sacrificial member has been removed. CVD, for example, is used for the formation of the conductive layer 35. Thereby, as shown in FIG. 18, stacked wiring lines including a select gate line SGD, word lines WL0 to WL7, and a select gate line SGS are formed.

Next, the sacrificial member 67 is removed (step S111). Thereby, the insulating film 66 provided in a bottom portion of the contact hole CH is exposed. In the processing of step S111, also the sacrificial member 68 in the contact hole C3H may be removed.

Next, the insulating film 66 in a bottom portion of the contact hole CH is removed (step S112). Thereby, in the bottom portion of each contact hole CH, the side surface of the conductive layer 35 associated with the contact hole CH is exposed.

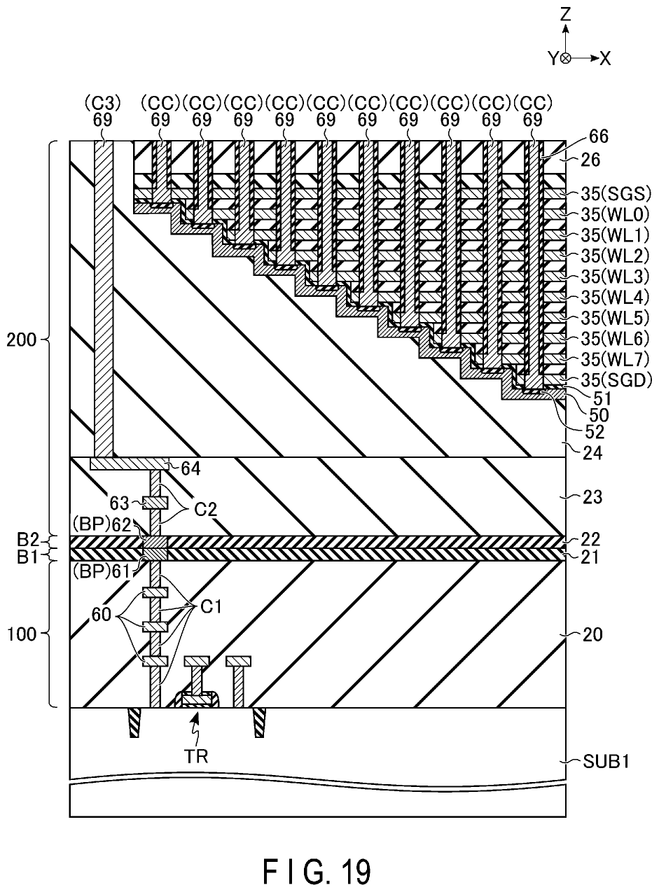

Next, as shown in FIG. 19, contacts CC are formed (step S113). Specifically, the inside of the contact hole CH is filled with a conductive member 69. Then, the conductive member 69 provided outside the contact hole CH is removed. Thereby, a structure corresponding to a contact CC is formed in each contact hole CH. In the processing of step S113, a conductive member 69 may be formed in the contact hole C3H. In this case, the conductive member 69 formed in the contact hole C3H corresponds to a contact C3.

By the manufacturing process described above, a structure corresponding to the stacked wiring lines of the memory layer 200 and a structure corresponding to the contacts CC are formed. Detailed processing corresponding to steps S111 to S113 will be described in the following item.

### <1-2-3> Detailed Method of Forming the Contact CC

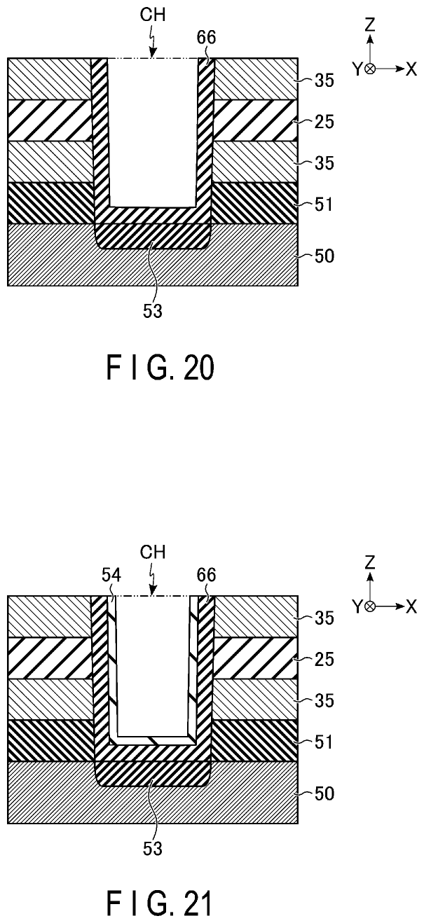

Each of FIGS. 20 to 26 is a cross-sectional view showing an example of a detailed cross-sectional structure in the formation process of the contact CC included in the memory device 1 according to the first embodiment. A method of forming the contact CC included in the memory device 1 according to the first embodiment will now be described.

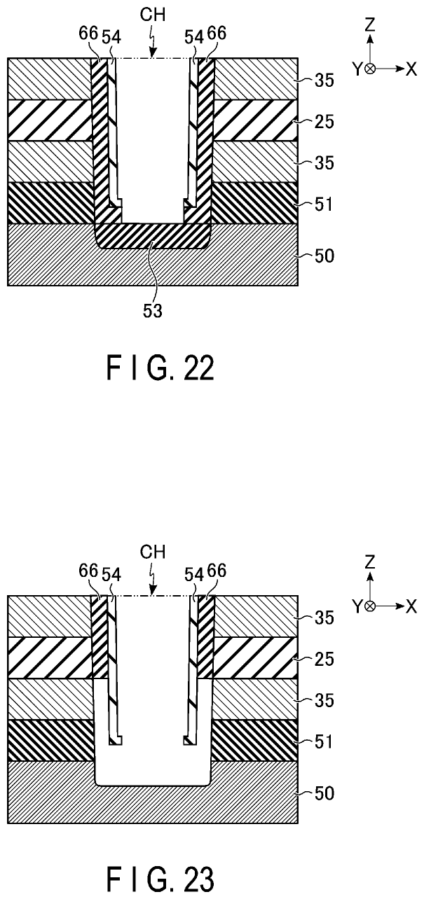

If the sacrificial member 67 is removed by the processing of step S111 shown in FIG. 10, a structure like that shown in FIG. 20 is formed. Next, as shown in FIG. 21, a sacrificial film 54 is formed along the insulating film 66 in the contact hole CH. The sacrificial film 54 is, for example, silicon nitride (SiN). Next, as shown in FIG. 22, the sacrificial film 54 and the insulating film 66 in a bottom portion of the contact hole CH are removed by anisotropic etching processing. Thereby, a part of the insulating film 66 and a part of the oxide film 53 are exposed in the bottom portion of the contact hole CH.

Next, as shown in FIG. 23, a part of the insulating film 66 and the oxide film 53 are selectively removed by, for example, wet etching processing. In this wet etching processing, conditions whereby the etching rate for the insulating film 66 and the oxide film 53 (for example, silicon oxide films) is higher than the etching rate for the sacrificial film 54 are used. Further, in this wet etching processing, the insulating film 66 is removed via a region between the sacrificial film 54 and the inner wall of the contact hole CH. Therefore, the area where the insulating film 66 is removed can be adjusted by controlling the etching time. Specifically, the area where the insulating film 66 is removed is adjusted such that the side surface of the conductive layer 35 associated with the contact hole CH is exposed and the side surface of the conductive layer 35 adjacent to the associated conductive layer 35 is not exposed.

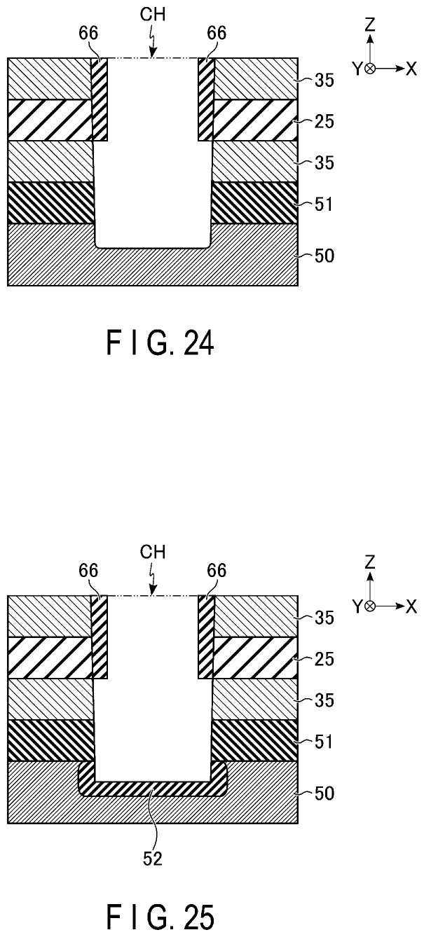

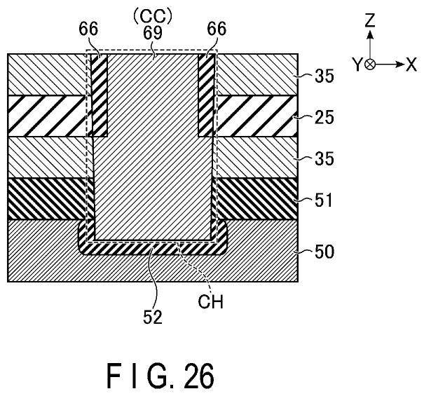

Next, as shown in FIG. 24, the sacrificial film 54 is removed. Next, as shown in FIG. 25, the stopper layer 50 exposed in a bottom portion of the contact hole CH is oxidized to form an oxide film 52. Thereby, a structure in which the contact hole CH and the stopper layer 50 are separated from each other by the insulating layer 51 and the oxide film 52 is formed. After that, as shown in FIG. 26, the inside of the contact hole CH is filled with a conductive member 69. Thereby, the conductive member 69 and the conductive layer 35 come into contact with each other, and are electrically connected to each other.

### <1-3> Effects of the First Embodiment

In the case of the memory device 1 according to the first embodiment described above, the manufacturing cost of the memory device 1 can be suppressed. Details of effects of the first embodiment will now be described.

As a method for increasing the storage capacity in a memory device in which memory cells are three-dimensionally stacked, it is conceivable to increase the number of stacked memory cells by increasing the number of stacked wiring lines such as word lines WL. However, in a case where the number of stacked memory cells is increased, the aspect ratio of etching processing executed at a depth penetrating the stacked wiring lines of the memory layer 200 is increased. The etching processing with a high aspect ratio has high cost, and thus can be a factor of increase in manufacturing cost of the memory device.

Thus, the memory device 1 according to the first embodiment has a bonded structure, and has a structure in which contacts CC for a staircase structure of stacked wiring lines are provided to penetrate from the back side of the staircase structure. Further, in the first embodiment, replacement processing for forming stacked wiring lines is executed after bonding processing. Then, etching processing for forming slits SLT for replacement processing and contact holes CH for contacts CC is collectively executed using the stopper layer 50 provided along the staircase structure of the stacked wiring lines (step S107).

Thus, in the memory device 1 according to the first embodiment, processes for forming the slit SLT and the contact hole CH can be integrated. As a result, in the method of manufacturing the memory device 1 according to the first embodiment, the number of steps of etching processing with a high aspect ratio can be reduced. Further, in the memory device 1 according to the first embodiment, a region between the staircase structure and the semiconductor substrate SUB1 is emptied, and bonding pads BP, etc. can be arranged. As a result, the memory device 1 according to the first embodiment can reduce the chip area. Therefore, the memory device 1 according to the first embodiment can suppress the manufacturing cost of the memory device 1 by reducing the number of manufacturing steps and reducing the chip area.

### <1-4> Modifications of the First Embodiment

The memory device 1 according to the first embodiment described above can be variously modified. For example, although the first embodiment has shown, as an example, a case where the contact CC is formed after replacement processing is executed, the present invention is not limited thereto. The contact CC may be formed simultaneously with the conductive layer 35 during replacement processing. Further, the structure of the contact CC in the first embodiment can be changed according to the method of manufacturing the memory device 1, as appropriate.

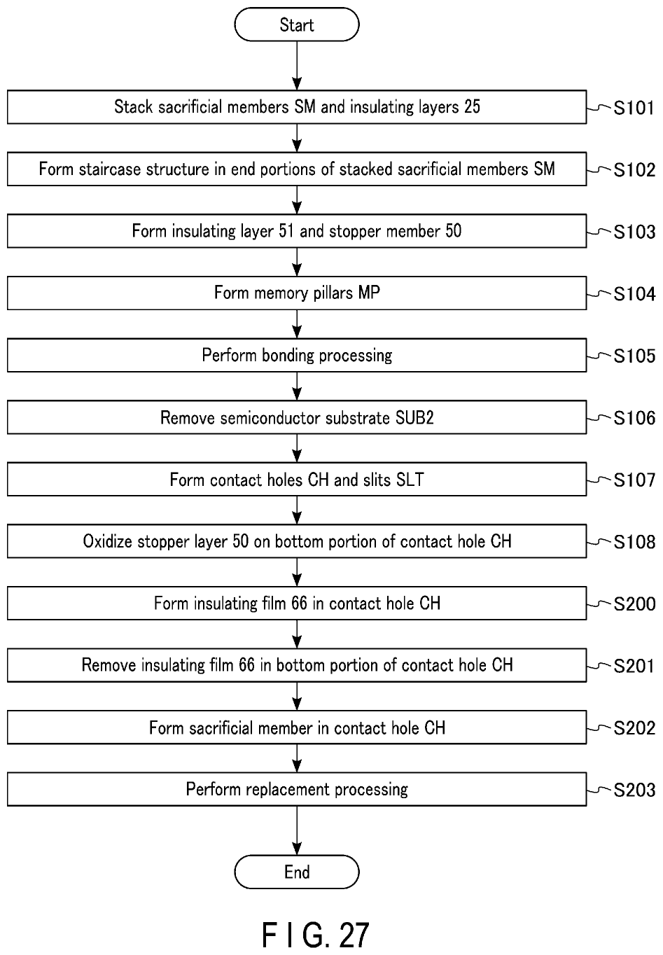

FIG. 27 is a flowchart showing an example of a method of manufacturing a memory device 1 according to a modification of the first embodiment. As shown in FIG. 27, the method of manufacturing the memory device 1 according to the modification of the first embodiment has a configuration in which the processing of steps S109 to S113 is replaced with the processing of steps S200 to S203 with respect to the flowchart described with reference to FIG. 10 in the first embodiment. Specifically, after the stopper layer 50 on a bottom portion of the contact hole CH is oxidized by the processing of step S108, an insulating film 66 is formed in the contact hole CH (step S200). Next, the insulating film 66 in a bottom portion of the contact hole CH is removed (step S201). In the processing of step S201, a part of the insulating film 66 is removed such that a part of the conductive layer 35 associated with the contact hole CH is exposed in the contact hole CH. Next, a sacrificial member is formed in the contact hole CH (step S202). As the sacrificial member formed in the processing of step S202, for example, the same material as the sacrificial member SM is used. Next, replacement processing is executed (step S203). By the processing of step S203, the sacrificial member formed by the processing of step S202 and the stacked sacrificial members SM are replaced with a conductor.

Hereinbelow, examples of the structure and the formation method of the contact CC in modifications of the first embodiment are described as a first to a third modification of the first embodiment. In the first to third modifications of the first embodiment, the formation process of the contact CC described using FIGS. 20 to 25 is common except that a sacrificial member SM occupies the space of the conductive layer 35 in FIGS. 20 to 25.

### (1: First Modification of the First Embodiment)

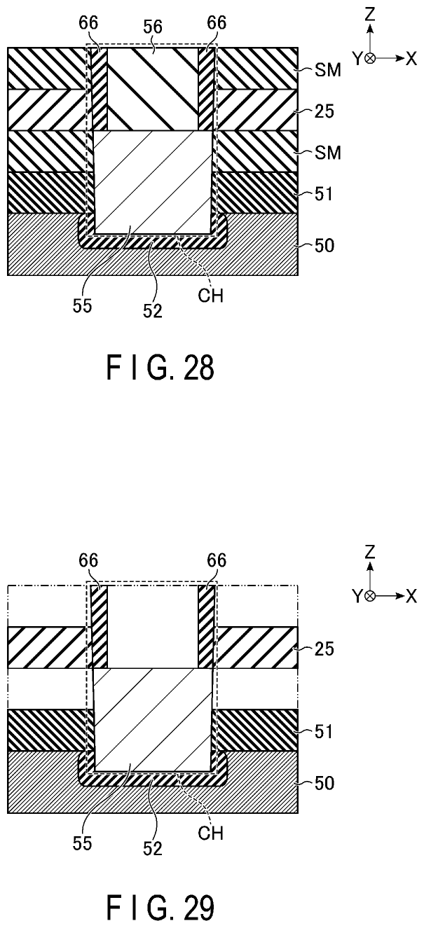

Each of FIGS. 28 to 30 is a cross-sectional view showing an example of a detailed cross-sectional structure in the formation process of the contact CC included in the memory device 1 according to a first modification of the first embodiment.

In the first modification of the first embodiment, after the structure shown in FIG. 25 is formed on the stacked structure of sacrificial members SM and insulating layers 25 before replacement processing is executed, as shown in FIG. 28, a semiconductor layer 55 is embedded in a bottom portion of the contact hole CH, and a sacrificial member 56 is embedded in the portion surrounded by the insulating film 66. In this processing, the semiconductor layer 55 may be provided in contact with the side surface of the associated sacrificial member SM. The semiconductor layer 55 is, for example, polysilicon. The sacrificial member 56 is, for example, silicon nitride.

Then, as shown in FIG. 29, in replacement processing, the stacked sacrificial members SM and the sacrificial member 56 in the contact hole CH are removed by, for example, wet etching processing. In this wet etching processing, conditions where the etching rate for the sacrificial members SM and 56 is higher than the etching rate for the semiconductor layer 55 are used. Therefore, the semiconductor layer 55 remains in a bottom portion of the contact hole CH.

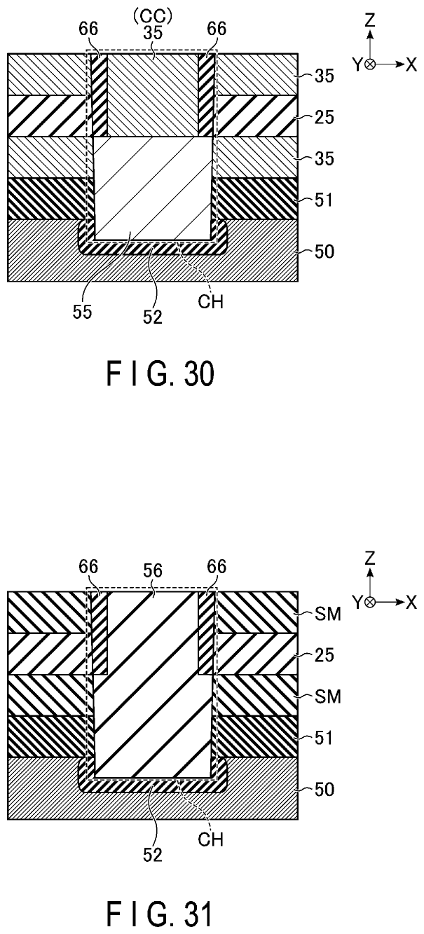

After that, as shown in FIG. 30, a conductive layer 35 is embedded in the space where the sacrificial members SM and 56 have been removed. As a result, the conductive layer 35 formed in the contact hole CH is used as a contact CC. A bottom portion of the conductive layer 35 formed in the contact hole CH is in contact with the semiconductor layer 55. Since the semiconductor layer 55 has conductivity, the conductive layer 35 in the contact hole CH and the conductive layer 35 associated with the contact hole CH among the stacked wiring lines are electrically connected to each other via the semiconductor layer 55.

### (2: Second Modification of the First Embodiment)

Each of FIGS. 31 to 33 is a cross-sectional view showing an example of a detailed cross-sectional structure in the formation process of the contact CC included in the memory device 1 according to a second modification of the first embodiment.

In the second modification of the first embodiment, after the structure shown in FIG. 25 is formed on the stacked structure of sacrificial members SM and insulating layers 25 before replacement processing is executed, a sacrificial member 56 is formed in the contact hole CH as shown in FIG. 31. That is, in the second modification of the first embodiment, a sacrificial member 56 is formed without a semiconductor layer 55 being formed in the contact hole CH as compared to the first modification of the first embodiment.

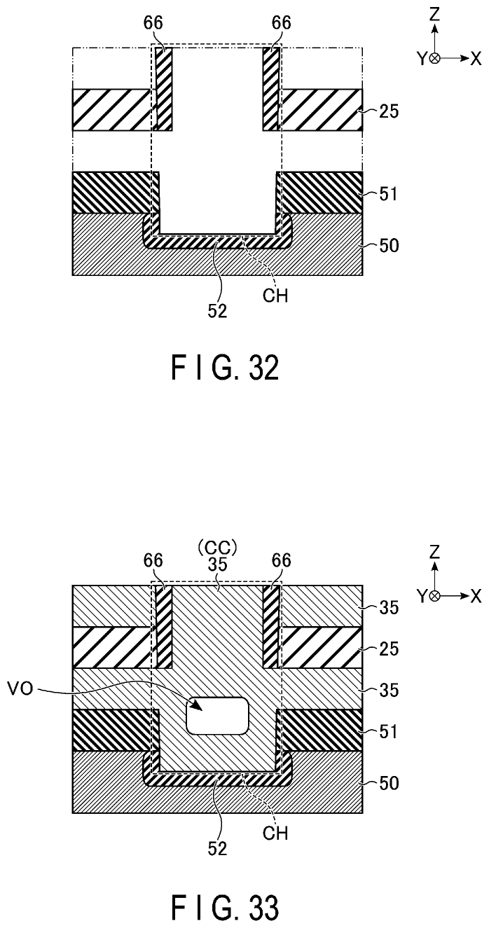

Then, as shown in FIG. 32, in replacement processing, the stacked sacrificial members SM and the sacrificial member 56 in the contact hole CH are removed by, for example, wet etching processing. Thereby, a bottom portion of the contact hole CH and a space portion where a wiring line associated with the contact hole CH is to be formed are connected to each other.

After that, as shown in FIG. 33, a conductive layer 35 is embedded in the space where the sacrificial members SM and 56 have been removed. As a result, the conductive layer 35 formed in the contact hole CH is used as a contact CC. In the second modification of the first embodiment, there is a portion where the conductive layer 35 in the contact hole CH and the conductive layer 35 associated with the contact hole CH among the stacked wiring lines are integrally provided. In the second modification of the first embodiment, a void VO may be provided in a bottom portion of the contact CC according to the method of forming the conductive layer 35.

### (3: Third Modification of the First Embodiment)

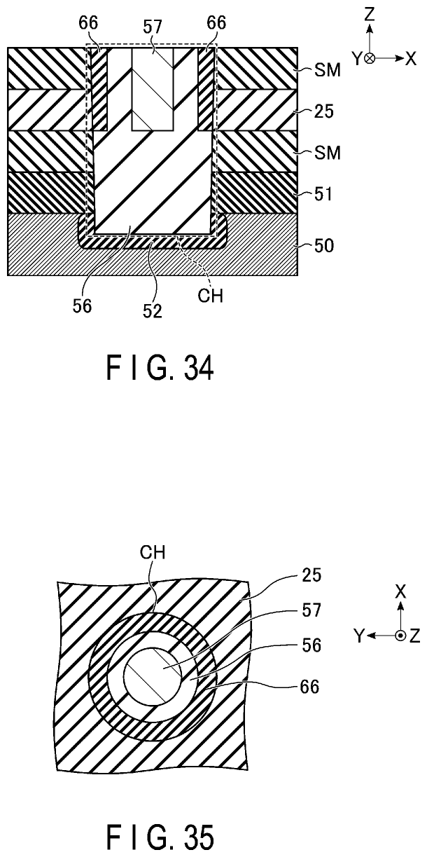

Each of FIGS. 34 and 35 is a cross-sectional view showing an example of a detailed cross-sectional structure in the formation process of the contact CC included in the memory device 1 according to a third modification of the first embodiment.

In the third modification of the first embodiment, after the structure shown in FIG. 25 is formed on the stacked structure of sacrificial members SM and insulating layers 25 before replacement processing is executed, sacrificial members 56 and 57 are formed in the contact hole CH as shown in FIG. 34. The sacrificial member 57 is a member different from the sacrificial member 56, and is, for example, amorphous silicon. As shown in FIG. 35, the sacrificial member 57 is provided in a central portion of the contact hole CH. The sacrificial member 56 surrounds the periphery of the sacrificial member 57. The insulating film 66 surrounds the periphery of the sacrificial member 56. Then, in replacement processing, the stacked sacrificial members SM and the sacrificial members 56 and 57 in the contact hole CH are removed by, for example, wet etching processing. In the third modification of the first embodiment, the sacrificial member 57 contains a material that is more apt to take etching selectivity than the sacrificial member 56. Thereby, remaining of the sacrificial members 56 and 57 in the contact hole CH can be avoided more than in the second modification of the first embodiment. After that, a conductive layer 35 is embedded in the space where the sacrificial members SM, 56, and 57 have been removed, and a structure like that shown in FIG. 33 can be formed like in the second modification of the first embodiment.

### <2> Second Embodiment

A memory device 1 according to a second embodiment has a structure in which a member functioning similarly to a stopper layer 50 is provided for each terrace portion of a staircase structure. Details of the second embodiment will now be described with emphasis on differences from the first embodiment.

### <2-1> Configuration

First, a configuration of the memory device 1 according to the second embodiment is described. The memory device 1 according to the second embodiment is different from the memory device 1 according to the first embodiment in the structure of the memory layer 200.

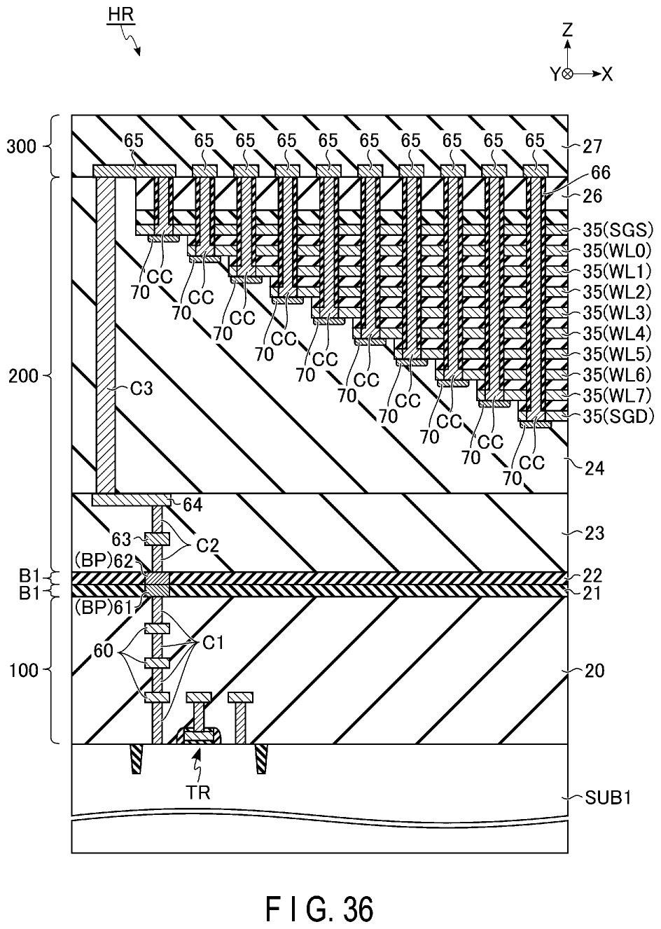

FIG. 36 is a cross-sectional view showing an example of a cross-sectional structure including a hookup region HR of the memory device 1 according to the second embodiment. FIG. 36 shows coordinate axes with a semiconductor substrate SUB1 as a reference. As shown in FIG. 36, the memory device 1 according to the second embodiment has a configuration in which a stopper layer 50 and an insulating layer 51 are omitted and a plurality of stopper members 70 are added as compared to the memory device 1 according to the first embodiment. Each of the stopper members 70 is in contact with a terrace portion of the associated wiring line (conductive layer 35).

Specifically, a stopper member 70 is provided on the lower surface of each terrace portion. In other words, the stopper members 70 are provided such that portions facing the terrace portions of the conductive layers 35 in the Z direction are apart from each other. Further, each of the stopper members 70 is apart from the conductive layer 35 adjacent to the associated conductive layer 35. An associated contact CC is in contact with each stopper member 70. The width of the stopper member 70 in a cross section perpendicular to the semiconductor substrate SUB1 is larger than the width of a bottom portion of the contact CC. As the stopper member 70, for example, polysilicon or tungsten is used.

Although illustration is omitted, a stopper member to be used during formation of a slit SLT may be provided in a region where the slit SLT is to be formed. Such a stopper member is, for example, placed between a portion where stacked wiring lines are formed and an insulating layer 23. The configuration of the other parts of the memory device 1 according to the second embodiment is similar to that of the first embodiment.

### <2-2> Manufacturing Method

Next, a method of manufacturing the memory device 1 according to the second embodiment is described.

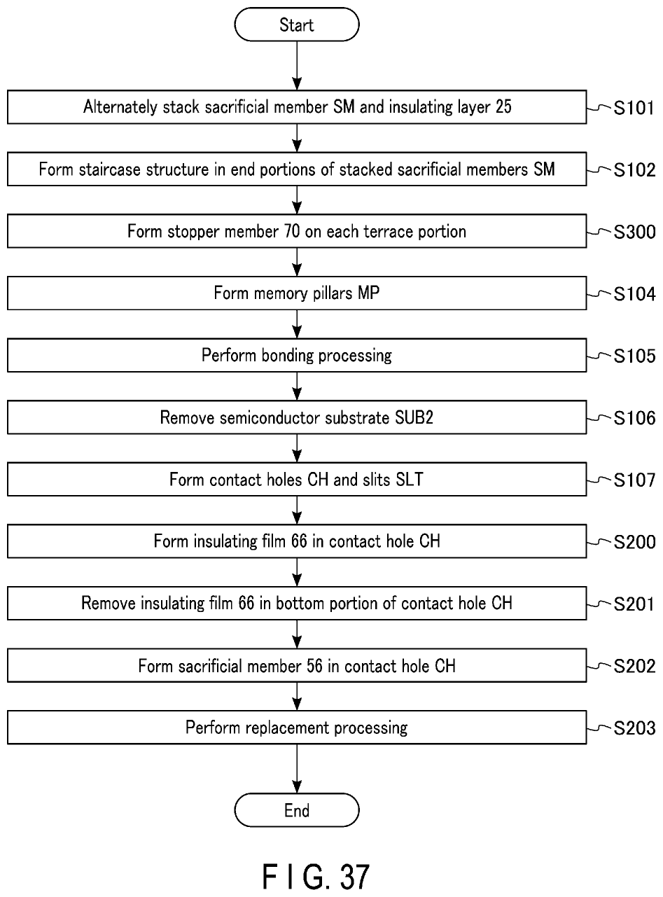

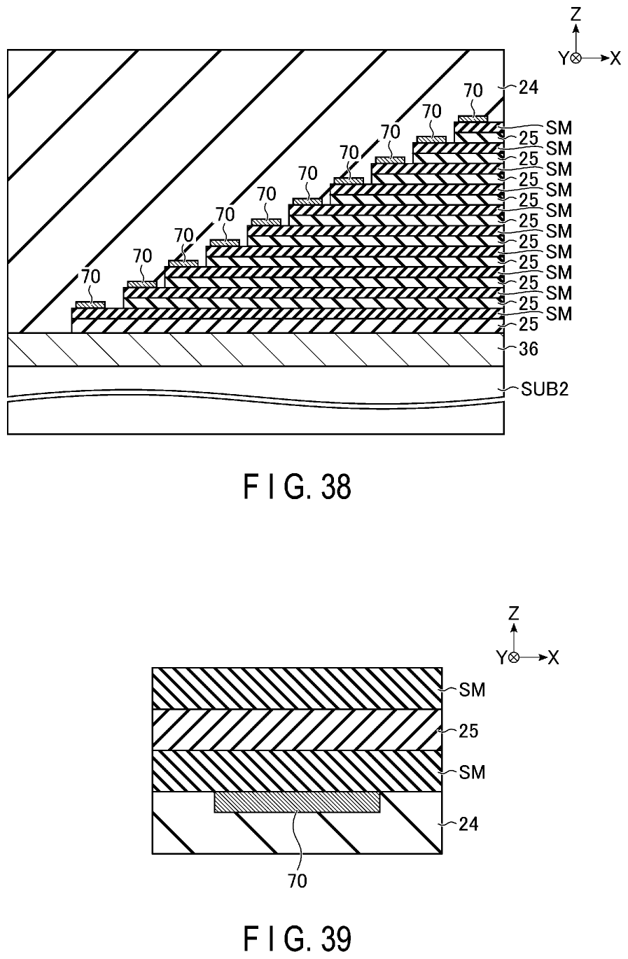

FIG. 37 is a flowchart showing an example of a method of manufacturing the memory device 1 according to the second embodiment. FIG. 38 is a cross-sectional view showing an example of a cross-sectional structure in the manufacturing process of the memory device 1 according to the second embodiment. Each of FIGS. 39 to 45 is a cross-sectional view showing an example of a detailed cross-sectional structure in the formation process of the contact CC included in the memory device 1 according to the second embodiment. A method of forming the stacked wiring lines and the contact CC included in the memory device 1 according to the second embodiment will now be described with reference to FIG. 37 as appropriate.

First, like in the first embodiment, a sacrificial member SM and an insulating layer 25 are alternately stacked (step S101). Next, like in the first embodiment, a staircase structure is formed in end portions of the stacked sacrificial members SM (step S102). Next, as shown in FIG. 38, a plurality of stopper members 70 are formed (step S103). Specifically, first, a stopper member 70 is formed to cover the staircase structure. Then, by a set of photolithography processing and etching processing, the stopper member 70 is processed to remain in a terrace portion of each of the stacked sacrificial members SM. After that, an insulating layer 24 is formed to fill the level difference portion formed by the stacked structure of sacrificial members SM and insulating layers 25. Then, the upper surface of the insulating layer 24 is planarized.

Next, like in the first embodiment, memory pillars MP are formed (step S104). Next, like in the first embodiment, bonding processing is executed (step S105). By the bonding processing, the terrace portion of the sacrificial member SM and the stopper member 70 are vertically inverted to become a structure like that shown in FIG. 39. Next, like in the first embodiment, the semiconductor substrate SUB2 is removed (step S106). After that, the conductive layer 36 is processed into a desired shape, and an insulating layer 26 is formed to cover the conductive layer 36.

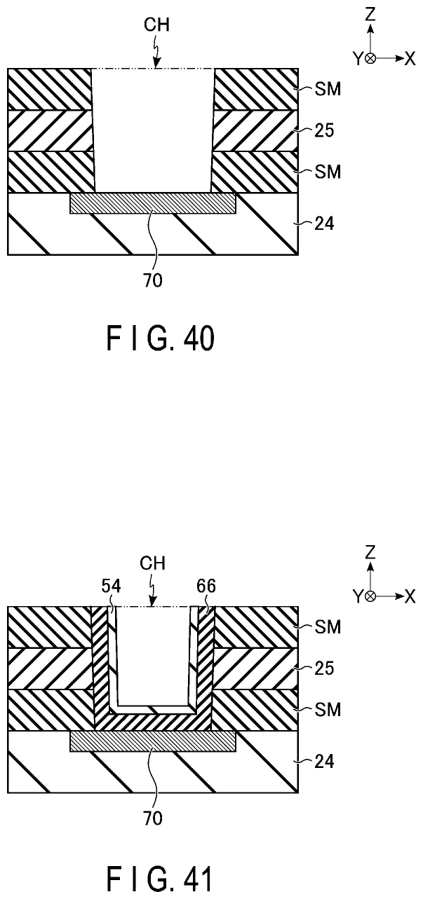

Next, contact holes CH and slits SLT are formed (step S107). In the processing of step S107, etching processing using the stopper member 70 as an etching stopper is executed. A plurality of contact holes CH are individually formed in regions corresponding to a plurality of contacts CC. Each contact hole CH is provided to penetrate the insulating layers 25 and 26 and at least one sacrificial member SM. As shown in FIG. 40, the stopper member 70 is exposed in a bottom portion of each contact hole CH. Although illustration is omitted, the slit SLT is provided to divide the stacked sacrificial members SM and insulating layers 25 like in the first embodiment.

Next, an insulating film 66 is formed in the contact hole CH (step S200). The insulating film 66 is provided along the contact hole CH.

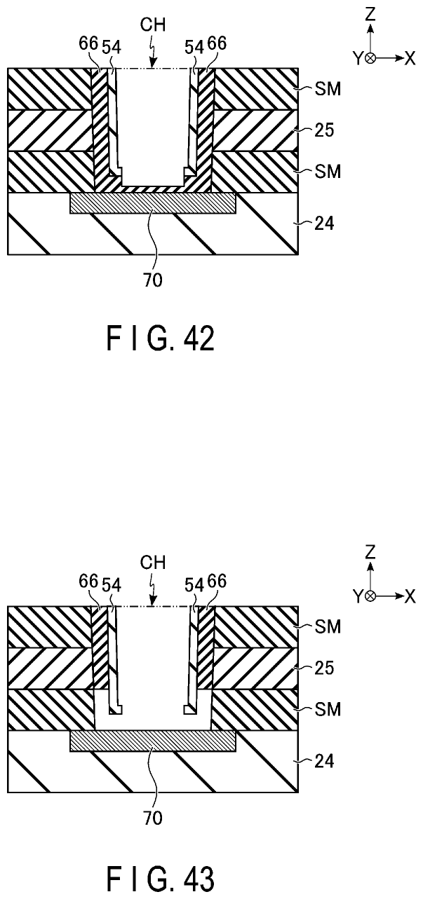

Next, the insulating film 66 in a bottom portion of the contact hole CH is removed (step S201). Specifically, first, as shown in FIG. 41, a sacrificial film 54 is formed along the insulating film 66 in the contact hole CH. Then, as shown in FIG. 42, the sacrificial film 54 in a bottom portion of the contact hole CH is removed by anisotropic etching processing. Thereby, a part of the insulating film 66 is exposed in the bottom portion of the contact hole CH. Then, as shown in FIG. 43, a part of the insulating film 66 is selectively removed by wet etching processing. In this wet etching processing, conditions whereby the etching rate for the insulating film 66 is higher than the etching rate for each of the sacrificial film 54 and the stopper member 70 are used. Further, in this wet etching processing, the insulating film 66 is removed via a region between the sacrificial film 54 and the inner wall of the contact hole CH. Therefore, the area where the insulating film 66 is removed can be adjusted by controlling the etching time. Specifically, the area where the insulating film 66 is removed is adjusted such that the side surface of the sacrificial member SM associated with the contact hole CH is exposed and the side surface of SM adjacent to the associated sacrificial member SM is not exposed.

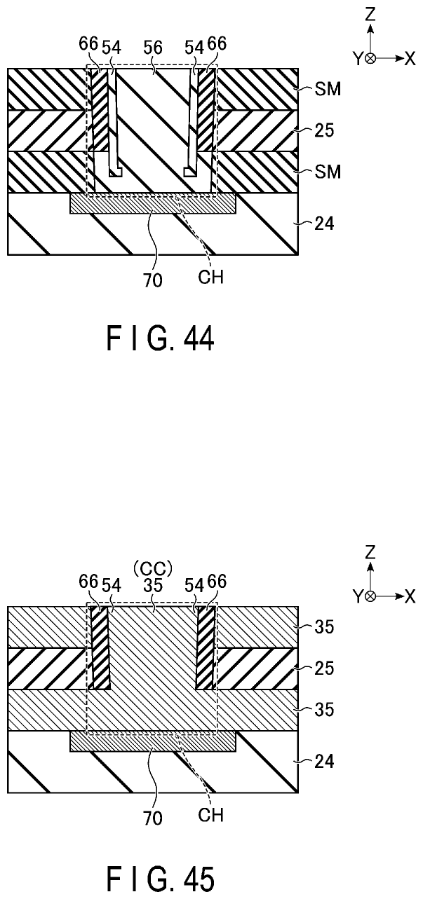

Next, as shown in FIG. 44, a sacrificial member 56 is formed in the contact hole CH (step S202). In the processing of step S202, the structure described in each of the first to third modifications of the first embodiment, that is, a structure in which the sacrificial film 54 is removed from the inside of the contact hole CH and the sacrificial member 57 or the semiconductor layer 55 is formed may be formed. In this case, after the sacrificial film 54 in the contact hole CH is removed, the structure in the contact hole CH shown in FIG. 28, 31, or 34 is formed.

Next, replacement processing is executed (step S203). Specifically, in replacement processing, the stacked sacrificial members SM, and the sacrificial member 56 (and the sacrificial film 57) in the contact hole CH are removed by, for example, wet etching processing. After that, as shown in FIG. 45, a conductive layer 35 is embedded in the space where the sacrificial members SM and 56 and the sacrificial film 54 have been removed. As a result, the conductive layer 35 formed in the contact hole CH is used as a contact CC. A bottom portion of the conductive layer 35 formed in the contact hole CH is provided integrally with and electrically connected to the conductive layer 35 associated with the contact hole CH among the stacked wiring lines. The method of manufacturing the other parts of the memory device 1 according to the second embodiment is similar to that of the first embodiment.

### <2-3> Effects of the Second Embodiment

In the memory device 1 according to the second embodiment, like in the first embodiment, the number of steps of etching processing with a high aspect ratio can be reduced, and the chip area can be reduced. Therefore, the memory device 1 according to the second embodiment can suppress the manufacturing cost of the memory device 1 by reducing the number of manufacturing steps and reducing the chip area.

### <3> Third Embodiment

A memory device 1A according to a third embodiment has a structure in which a plurality of memory layers 200 are stacked. Then, in the memory device 1A according to the third embodiment, contacts CC for some stacked wiring lines connected to stacked memory cells are coupled in the Z direction. Details of the third embodiment will now be described with emphasis on differences from the first or second embodiment.

### <3-1> Configuration

First, a configuration of the memory device 1A according to the third embodiment is described.

### <3-1-1> Overall Configuration of the Memory Device 1A

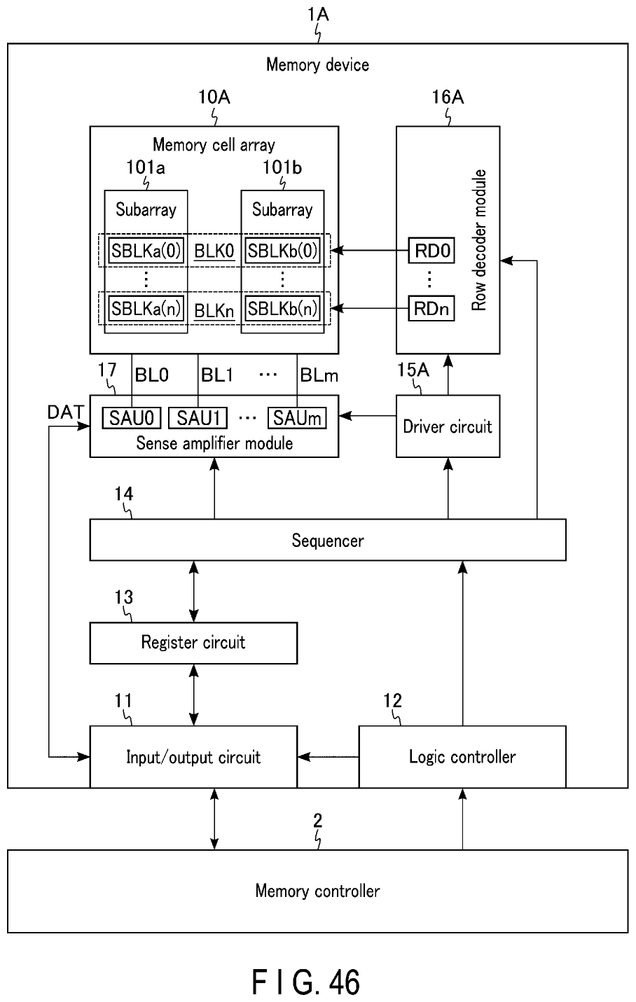

FIG. 46 is a block diagram showing an example of an overall configuration of a memory system including the memory device 1A according to the third embodiment. As shown in FIG. 46, the memory device 1A includes, for example, a memory cell array 10A, an input/output circuit 11, a logic controller 12, a register circuit 13, a sequencer 14, a driver circuit 15A, a row decoder module 16A, and a sense amplifier module 17. The configurations of the input/output circuit 11, the logic controller 12, the register circuit 13, the sequencer 14, and the sense amplifier module 17 in the memory device 1A are similar to those of the first embodiment.

The memory cell array 10A includes subarrays 101a and 101b. The subarrays 101a and 101b are formed using different semiconductor substrates. The subarray 101a includes a plurality of subblocks SBLKa(0) to SBLKa(n) (“n” is an integer of 1 or more). The subarray 101b includes a plurality of subblocks SBLKb(0) to SBLKb(n). In the memory cell array 10A, a set of subblocks SBLKa(k) and SBLKb(k) (“k” is an integer of 0 or more and n or less) constitutes one block BLKk. In other words, the memory cell array 10A includes a plurality of blocks BLK0 to BLKn each including a set of one subblock SBLKa included in the subarray 101a and one subblock SBLKb included in the subarray 101b. The memory cell array 10A may include three or more subarrays 101. In this case, the block BLK includes a set of subblocks SBLK of the subarrays 101.

Each of the driver circuit 15A and the row decoder module 16A is configured to be compatible with the circuit configuration of the memory cell array 10A. The driver circuit 15A generates voltage to be applied to various wiring lines provided in the subarray 101a and the subarray 101b. The row decoder module 16A includes a plurality of row decoders RD0 to RDn associated with the blocks BLK0 to BLKn, respectively. Each row decoder RD of the row decoder module 16A transfers voltage generated by the driver circuit 15A to various wiring lines provided in the subarray 101a and the subarray 101b.

### <3-1-2> Circuit Configuration of the Memory Cell Array 10A

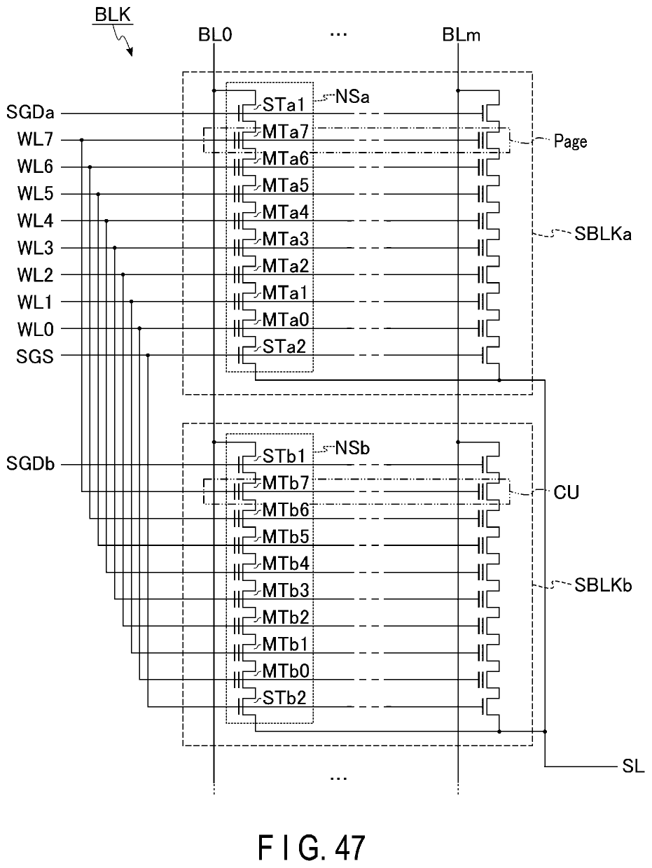

FIG. 47 is a circuit diagram showing an example of a circuit configuration of the memory cell array 10A included in the memory device 1A according to the third embodiment. FIG. 47 shows one block BLK among the blocks BLK included in the memory cell array 10A. As shown in FIG. 47, select gate lines SGDa, SGDb, and SGS, word lines WL0 to WL7, bit lines BL0 to BLm, and a source line SL are connected to the block BLK of the third embodiment. The select gate lines SGDa, SGDb, and SGS and the word lines WL0 to WL7 are provided for each block BLK. Each of the bit lines BL0 to BLm and the source line SL is shared by, for example, a plurality of blocks BLK.

In the block BLK of the third embodiment, each subblock SBLKa includes a plurality of NAND strings NSa. Each subblock SBLKb includes a plurality of NAND strings NSb. The NAND strings NSa are individually associated with the bit lines BL0 to BLm. The NAND strings NSb are individually associated with the bit lines BL0 to BLm. Each of the NAND strings NSa and NSb is connected between the associated bit line BL and the source line SL.

Each NAND string NSa includes, for example, memory cell transistors MTa0 to MTa7 and select transistors STa1 and STa2. Each of the select transistors STa1 and STa2 is used to select the subblock SBLKa. In each NAND string NSa, the select transistor STa1, the memory cell transistors MTa7 to MTa0, and the select transistor STa2 are connected in series in this order from the bit line BL toward the source line SL.

Each NAND string NSb includes, for example, memory cell transistors MTb0 to MTb7 and select transistors STb1 and STb2. Each of the select transistors STb1 and STb2 is used to select the subblock SBLKb. In each NAND string NSb, the select transistor STb1, the memory cell transistors MTb7 to MTb0, and the select transistor STb2 are connected in series in this order from the bit line BL toward the source line SL.

The select gate lines SGDa and SGDb are associated with the subblocks SBLKa and SBLKb, respectively. The select gate line SGDa is connected to a gate end of each of the select transistors STa1 included in the associated subblock SBLKa. The select gate line SGDb is connected to a gate end of each of the select transistors STb1 included in the associated subblock SBLKb. That is, in the third embodiment, the select gate line SGD is provided for each subblock SBLK.

A word line WL(K) (“K” is, for example, an integer of 0 or more and 7 or less) of the third embodiment is connected to a control gate end of each of a plurality of memory cell transistors MTa (K) and a control gate end of each of a plurality of memory cell transistors MTb (K) included in the associated block BLK. That is, in the memory cell array 10A, the word line WL is shared by a set of subblocks SBLKa and SBLKb combined.

The select gate line SGS of the third embodiment is connected to a gate end of each of a plurality of select transistors STa2 and a gate end of each of a plurality of select transistors STb2 included in the associated block BLK. That is, in the memory cell array 10A, the select gate line SGS is shared by a set of subblocks SBLKa and SBLKb combined.

The memory cell array 10A may be another circuit configuration. For example, the select gate line SGS may be provided for each subblock SBLK similarly to the select gate line SGD. Further, a plurality of independently controllable select gate lines SGD may be provided in each of the subblocks SBLKa and SBLKb. In this case, each subblock SBLK is configured such that selection can be performed in units of a plurality of units individually associated with the select gate lines SGD. In a case where the memory cell array 10A includes three or more subarrays 101, for example, the word line WL is shared among a plurality of subblocks SBLK in the same block BLK, and the select gate line SGD is connected in an independently controllable manner.

In the following, a case where word lines WL0 to WL7 are provided for each block BLK and NAND strings NSa and NSb respectively include eight memory cell transistors MT and share the word lines WL0 to WL7 associated with the eight memory cell transistors MT is described as an example.

### <3-1-3> Structure of the Memory Device 1A

A structure of the memory device 1A according to the third embodiment will now be described.

### (1: External Appearance of the Memory Device 1A)

First, an external appearance of the memory device 1A according to the third embodiment is described. The memory device 1A according to the third embodiment is formed by a method in which three semiconductor circuit substrates each with a semiconductor circuit formed thereon are bonded together and the bonded semiconductor circuit substrates are separated on a chip basis. Specifically, the memory device 1A according to the third embodiment has a structure formed by bonding semiconductor substrates SUB1 to SUB3 together. Each of the semiconductor substrates SUB1 to SUB3 is a silicon substrate. In the following, a case where the semiconductor substrates SUB2 and SUB3 are removed in the manufacturing process of the memory device 1A is described. A part of each of the semiconductor substrates SUB2 and SUB3 may remain after the semiconductor substrates SUB1 to SUB3 are bonded together.

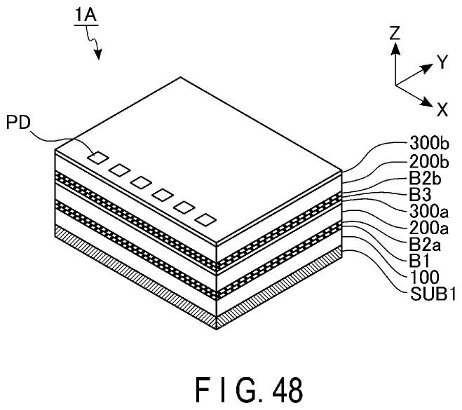

FIG. 48 is a perspective view showing an example of an external appearance of the memory device 1A according to the third embodiment. As shown in FIG. 48, the memory device 1A has a structure in which, for example, the semiconductor substrate SUB1, a CMOS layer 100, a bonding layer B1, a bonding layer B2a, a memory layer 200a, a wiring layer 300a, a bonding layer B3, a bonding layer B2b, a memory layer 200b, and a wiring layer 300b are stacked in this order from the bottom.

Like in the first embodiment, the CMOS layer 100 includes a CMOS circuit formed using the semiconductor substrate SUB1. The CMOS layer 100 of the third embodiment includes, for example, the input/output circuit 11, the logic controller 12, the register circuit 13, the sequencer 14, the driver circuit 15A, the row decoder module 16A, and the sense amplifier module 17.

The bonding layer B1 is formed using the semiconductor substrate SUB1, and includes a plurality of bonding pads electrically connected to the CMOS circuit provided in the CMOS layer 100 and forming parts of the semiconductor circuit. The bonding layer B2a is formed using the semiconductor substrate SUB2 (not illustrated), and includes a plurality of bonding pads electrically connected to the portion of the memory cell array 10A provided in the memory layer 200a and forming parts of the semiconductor circuit. The bonding pads included in the bonding layer B1 are individually connected to a plurality of bonding pads BP included in the bonding layer B2a. A portion between the bonding layers B1 and B2a corresponds to a boundary portion between a layer formed using the semiconductor substrate SUB1 and a layer formed using the semiconductor substrate SUB2 (not illustrated).

The memory layer 200a is formed using the semiconductor substrate SUB2, and includes the subarray 101a. The wiring layer 300a includes wiring lines, etc. connected to the semiconductor circuit provided in the memory layer 200a.

The wiring layer 300a and the bonding layer B3 are formed using the semiconductor substrate SUB1 after the semiconductor substrates SUB1 and SUB2 are bonded together. The bonding layer B3 includes a plurality of bonding pads connected to the portion of the memory cell array 10A provided in the memory layer 200a via the wiring layer 300a and forming parts of the semiconductor circuit. The bonding layer B2b is formed using the semiconductor substrate SUB3 (not illustrated), and includes a plurality of bonding pads electrically connected to the portion of the memory cell array 10A provided in the memory layer 200b and forming parts of the semiconductor circuit. The bonding pads included in the bonding layer B3 are individually connected to a plurality of bonding pads BP included in the bonding layer B2b. A portion between the bonding layers B3 and B2b corresponds to a boundary portion between a layer formed using the semiconductor substrate SUB2 (not illustrated) and a layer formed using the semiconductor substrate SUB3 (not illustrated).

The memory layer 200b is formed using the semiconductor substrate SUB3, and includes the subarray 101b. The wiring layer 300b includes wiring lines, etc. connected to the semiconductor circuit provided in the memory layer 200b. Further, the wiring layer 300b includes a plurality of pads PD. The pads PD are exposed on a surface of the memory device 1A. The pads PD are used for connection between the memory device 1A and the memory controller 2, etc.

### (2: Cross-Sectional Structure of the Memory Device 1A)

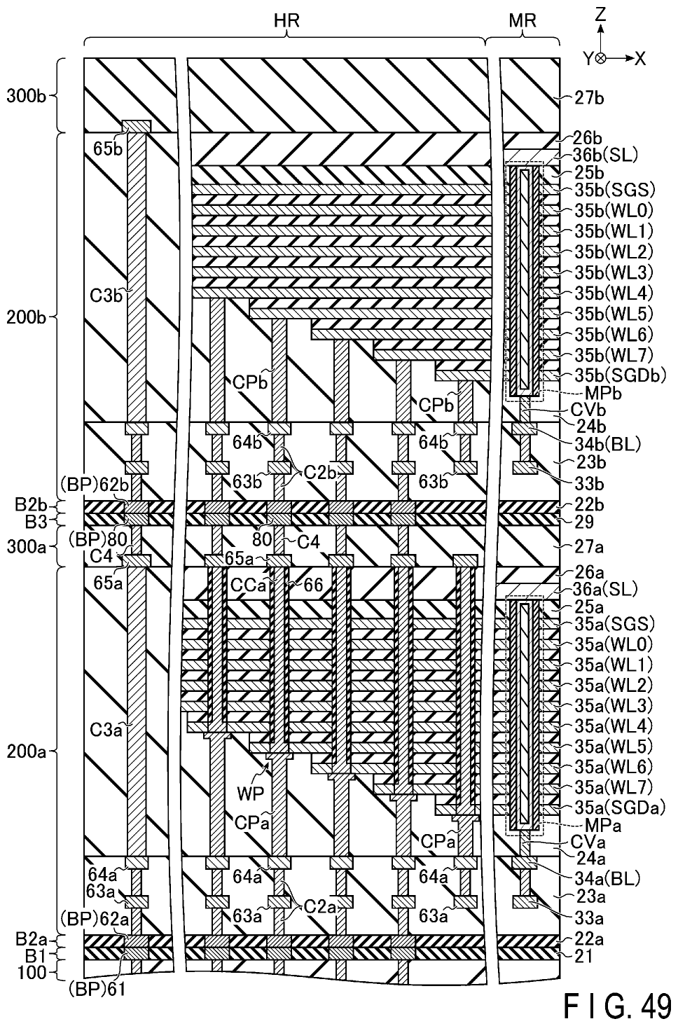

FIG. 49 is a cross-sectional view showing an example of a cross-sectional structure of the memory device 1A according to the third embodiment. FIG. 49 shows coordinate axes with the semiconductor substrate SUB1 (not illustrated) as a reference. As shown in FIG. 49, each of the memory layers 200a and 200b has a configuration similar to that of the memory layer 200 of the first embodiment except that the configuration of the contact in the hookup region HR is different and the stopper layer 50 and the insulating layer 51 are omitted. Each of the bonding layers B2a and B2b has a configuration similar to that of the bonding layer B2 of the first embodiment. In the following description, for a configuration included in the memory layer 200a and similar to the memory layer 200, “a” is added to the end of the reference sign. For a configuration included in the memory layer 200b and similar to the memory layer 200, “b” is added to the end of the reference sign. For a configuration included in the bonding layer B2a and similar to the bonding layer B2, “a” is added to the end of the reference sign. For a configuration included in the bonding layer B2b and similar to the bonding layer B2, “b” is added to the end of the reference sign.

The memory layer 200a includes a plurality of contacts CPa, CCa, C2a, C3a, and CVa. Each contact CPa has a shape extending in the Z direction and provided on a conductive layer 64a. Each contact CPa is connected to a terrace portion of an associated conductive layer 35a from the semiconductor substrate SUB1 side (that is, the front side of a staircase structure of a plurality of conductive layers 35a). On the other hand, each contact CCa is connected to the terrace portion of the associated conductive layer 35a from the wiring layer 300a side (that is, the back side of the staircase structure of the conductive layers 35a). That is, each contact CPa is coupled to the contact CCa associated with the same conductive layer 35a in the Z direction. In other words, the contact CCa associated with the same conductive layer 35a is provided on each contact CPa.

Each contact CPa has a wide portion WP in an upper portion. In a cross section perpendicular to the semiconductor substrate SUB1, the width of the wide portion WP is larger than the width of a bottom portion of the contact CCa. That is, the contact CPa has a first portion and a second portion (the wide portion WP) of which the side surface is, on the first portion, provided discontinuously with the first portion. In a boundary portion between the first portion and the second portion of the contact CPa, the area of the second portion of the contact CPa in the XY plane parallel to the surface of the semiconductor substrate SUB1 is larger than the area of the first portion of the contact CPa in the XY plane parallel to the surface of the semiconductor substrate SUB1. In other words, in the boundary portion between the first portion and the second portion of the contact CPa, the diameter of the second portion of the contact CPa is larger than the diameter of the first portion of the contact CPa. Further, in a boundary portion between the contact CPa and the contact CCa connected together, the area of the second portion (the wide portion WP) of the contact CPa in the XY plane parallel to the surface of the semiconductor substrate SUB1 is larger than the area of the contact CCa in the XY plane parallel to the surface of the semiconductor substrate SUB1. In other words, in the boundary portion between the contact CPa and the contact CCa connected together, the diameter of the second portion (the wide portion WP) of the contact CPa is larger than the diameter of the contact CCa.

The wiring layer 300a includes a plurality of conductive layers 65a and a plurality of contacts C4 provided on the conductive layers 65a. The bonding layer B3 includes an insulating layer 29 and a plurality of conductive layers 80. The memory layer 200b includes a plurality of contacts CPb, C2b, C3b, and CVb. The wiring layer 300b includes a plurality of conductive layers 65b. Each conductive layer 65a is connected to the contact C3a or CCa. Each contact C4 is provided on the associated conductive layer 65a. The insulating layer 29 is provided on an insulating layer 27a of the wiring layer 300a. Each conductive layer 80 is provided on the associated contact C4. The conductive layer 80 is used as a bonding pad BP. An insulating layer 22b of the bonding layer B2b is provided on the insulating layer 29 of the bonding layer B3. The two bonding pads BP arranged to face each other between the bonding layers B2b and B3 are connected to each other. Each contact CPb has a shape extending in the Z direction and provided on a conductive layer 64b. Each contact CPb is connected to a terrace portion of an associated conductive layer 35b from the semiconductor substrate SUB1 side (that is, the front side of a staircase structure of conductive layers 35b). The conductive layer 65b is provided on the associated contact C3b.

In the third embodiment, stacked wiring lines associated between the memory layer 200a and the memory layer 200b are short-circuited. Specifically, a set of conductive layers 35a and 35b used as the select gate line SGS are connected to each other via conductive layers 65a, 80, and 62b to 64b and contacts C4, C2b, CCa, and CPb coupled in the Z direction. Further, the set of conductive layers 35a and 35b used as the select gate line SGS are connected to the semiconductor circuit in the CMOS layer 100 via contacts CPa and C2a and conductive layers 62a to 64a. Similarly, a set of conductive layers 35a and 35b used as the word line WL are connected to each other via conductive layers 65a, 80, and 62b to 64b and contacts C4, C2b, CCa, and CPb coupled in the Z direction. Further, the set of conductive layers 35a and 35b used as the word line WL are connected to the semiconductor circuit in the CMOS layer 100 via contacts CPa and C2a and conductive layers 62a to 64a. On the other hand, each of the conductive layer 35a used as the select gate line SGDa and the conductive layer 35b used as the select gate line SGDb is independently electrically connected to the semiconductor circuit in the CMOS layer 100.

The conductive layer 65b in the wiring layer 300b can be connected to the semiconductor circuit in the CMOS layer 100 via contacts C2a, C3a, C4, C2b, and C3b and conductive layers 62a to 65a, 62b to 64b, and 80. Although illustration is omitted, conductive layers 34 (bit lines BL) associated between the memory layers 200a and 200b are short-circuited between the memory layers 200a and 200b, and are electrically connected to the semiconductor circuit in the CMOS layer 100. Although illustration is omitted, a stopper member to be used during formation of a slit SLT of the memory layer 200a may be provided in a region where the slit SLT is to be formed. Such a stopper member is, for example, placed between a portion of the memory layer 200a where stacked wiring lines are formed and an insulating layer 23a. The configuration of the other parts of the memory device 1A according to the third embodiment is similar to that of the memory device 1 according to the first embodiment.

### <3-2> Manufacturing Method

Next, a method of manufacturing the memory device 1A according to the third embodiment is described.

### <3-2-1> Method of Forming the Stacked Wiring Lines and the Contact CCa

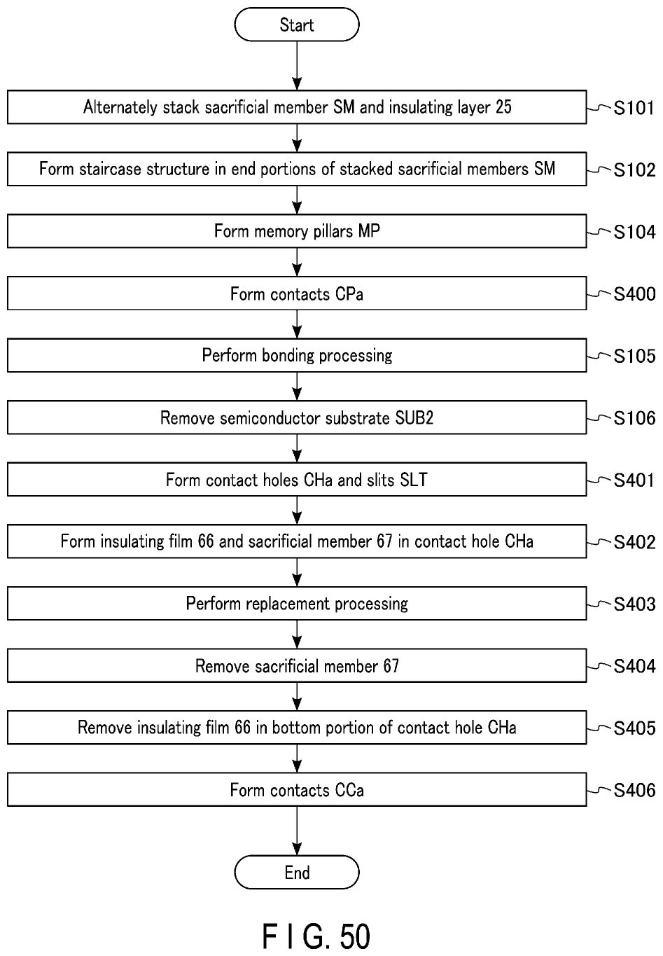

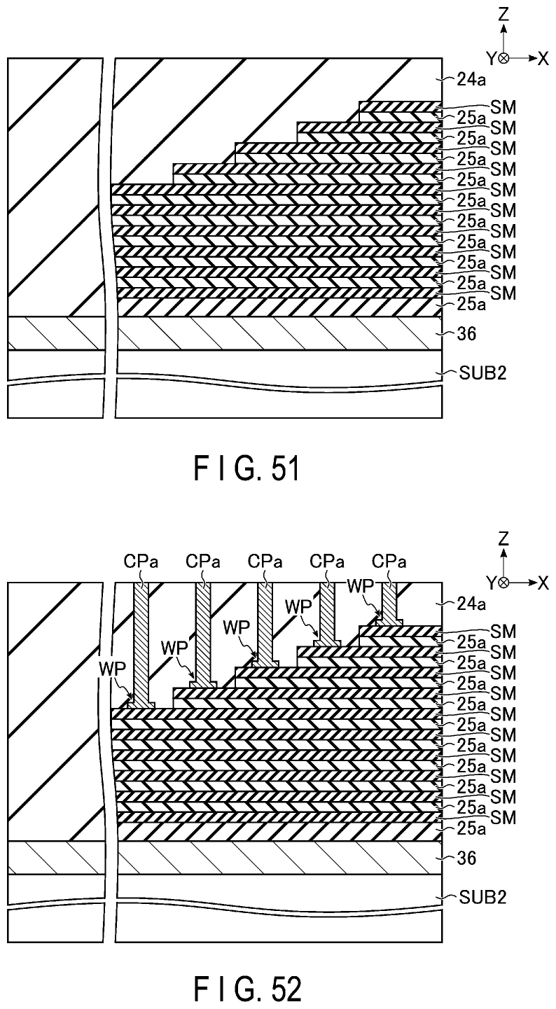

FIG. 50 is a flowchart showing an example of a method of manufacturing the memory device according to the third embodiment. Each of FIGS. 51 to 57 is a cross-sectional view showing an example of a cross-sectional structure in the manufacturing process of the memory device according to the third embodiment. A method of forming the stacked wiring lines and the contact CCa in the memory device 1A according to the third embodiment will now be described with reference to FIG. 50 as appropriate.

First, like in the first embodiment, a sacrificial member SM and an insulating layer 25 are alternately stacked (step S101). Next, like in the first embodiment, a staircase structure is formed in end portions of the stacked sacrificial members SM (step S102). Next, as shown in FIG. 51, an insulating layer 24a is formed to fill the level difference portion formed by the stacked structure of sacrificial members SM and insulating layers 25. Then, the upper surface of the insulating layer 24a is planarized. Next, like in the first embodiment, memory pillars MP are formed (step S104).

Next, as shown in FIG. 52, contacts CPa are formed (step S400). Each contact CPa is provided to penetrate the insulating layer 24a, and is connected to a terrace portion of the associated sacrificial member SM. A wide portion WP is formed in each contact CPa. Details of the method of forming the wide portion WP will be described later.

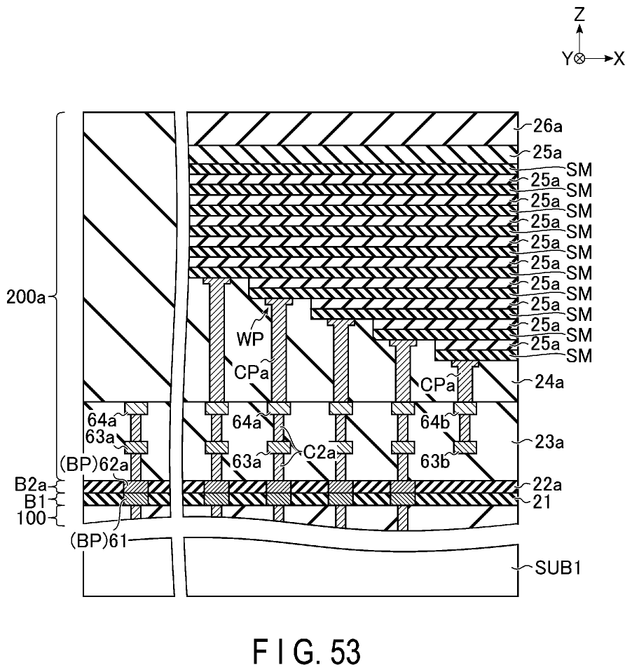

Next, like in the first embodiment, bonding processing is executed (step S105). Next, like in the first embodiment, the semiconductor substrate SUB2 is removed (step S106). After that, a conductive layer 36a is processed into a desired shape, and as shown in FIG. 53, an insulating layer 26a is formed to cover the conductive layer 36a in a not-illustrated region.

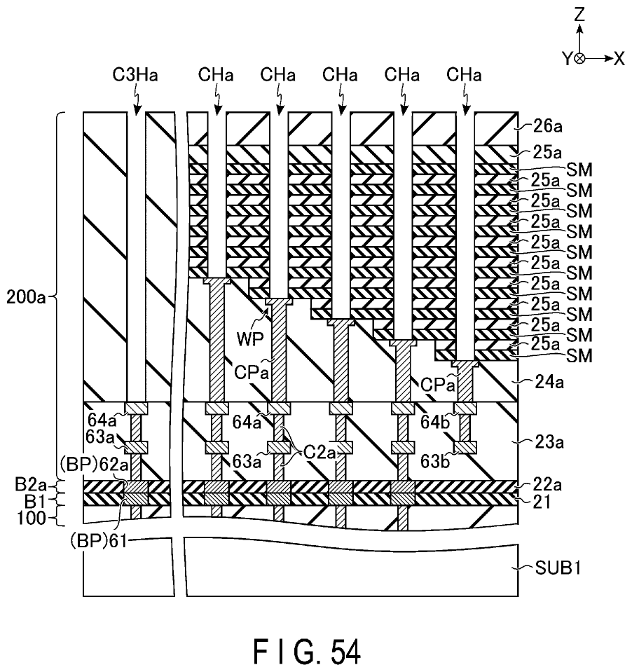

Next, contact holes CHa and slits SLT are formed (step S401). In the processing of step S401, etching processing using the wide portion WP of the contact CPa as an etching stopper is executed. A plurality of contact holes CHa are individually formed in regions corresponding to a plurality of contacts CCa. Each contact hole CHa is provided to penetrate the insulating layers 25a and 26a and at least one sacrificial member SM. As shown in FIG. 54, a part of the associated contact CPa is exposed in a bottom portion of each contact hole CHa. Although illustration is omitted, the slit SLT is provided to divide the stacked sacrificial members SM and insulating layers 25a like in the first embodiment. In the processing of step S401, contact holes C3Ha may be simultaneously formed. The contact hole C3Ha is formed in a region corresponding to a contact C3. The contact hole C3Ha is provided to penetrate the insulating layer 24a. A conductive layer 64a is exposed in a bottom portion of the contact hole C3Ha.

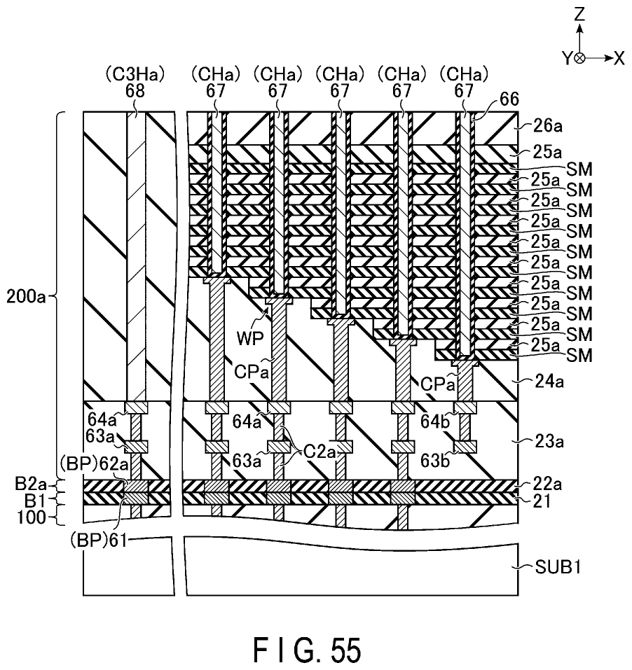

Next, as shown in FIG. 55, an insulating film 66 and a sacrificial member 67 are formed in the contact hole CHa (step S402). The insulating film 66 is provided along the contact hole CHa. The sacrificial member 67 is embedded inside of the insulating film 66 in the contact hole CHa. In the present example, a sacrificial member 68 is formed in the contact hole C3Ha. The sacrificial member 68 may be formed in a process different from that of the sacrificial member 67, or may be formed simultaneously with the sacrificial member 67. Like in the contact hole CHa, an insulating film 66 and a sacrificial member 67 may be formed in the contact hole C3Ha.

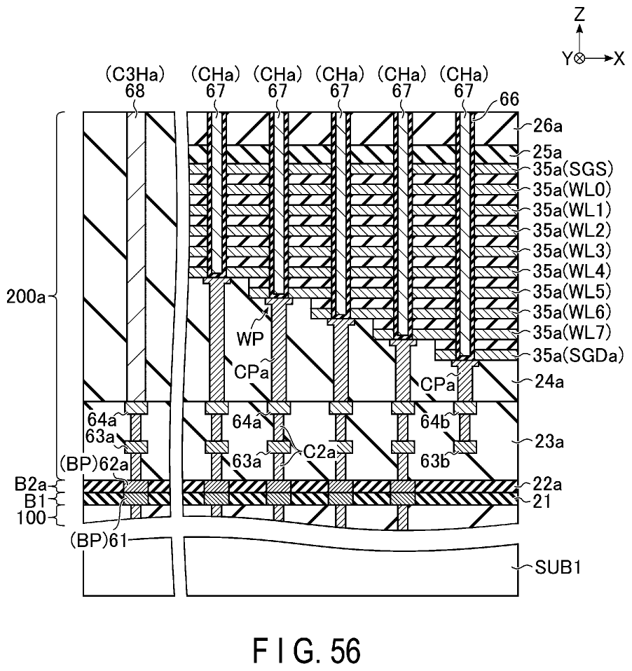

Next, replacement processing is executed (step S403). Specifically, in replacement processing, the stacked sacrificial members SM are removed by, for example, wet etching processing using hot phosphoric acid or the like. After that, as shown in FIG. 56, a conductive layer 35a is embedded in the space where the sacrificial member SM has been removed. As a result, a plurality of conductive layers 35a corresponding to stacked wiring lines of the memory layer 200a are formed.

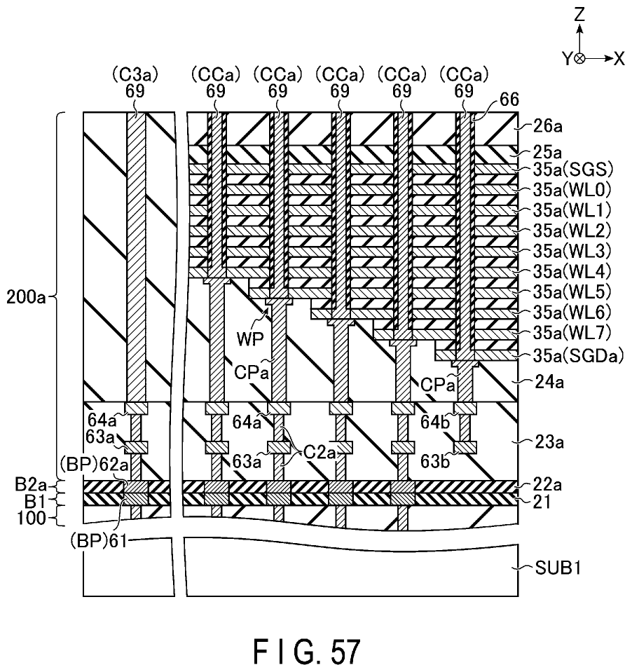

Next, the sacrificial member 67 is removed (step S404). Then, the insulating film 66 in a bottom portion of the contact hole CHa is removed (step S405). Then, as shown in FIG. 57, contacts CCa are formed (step S406). Specifically, the inside of the contact hole CH is filled with a conductive member 69. Thereby, the conductive member 69 used as the contact CCa and the conductive layer 35 come into contact with each other, and are electrically connected to each other.

### <3-2-2> Detailed Method of Forming the Contact CPa

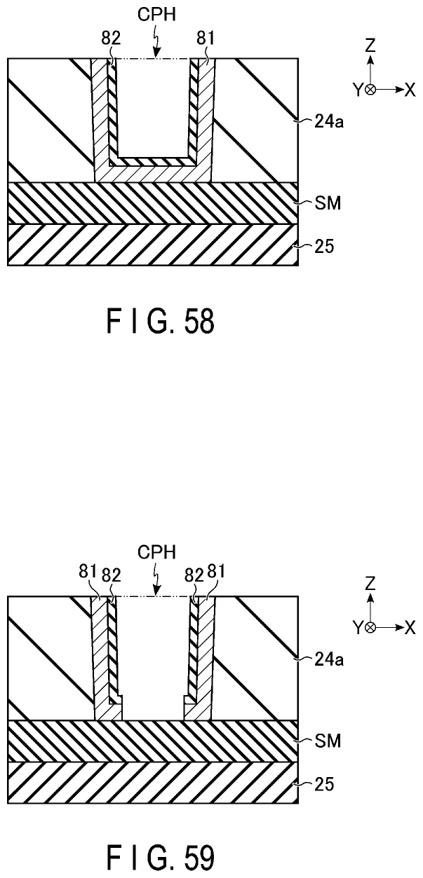

Each of FIGS. 58 to 61 is a cross-sectional view showing an example of a detailed cross-sectional structure in the formation process of a contact included in the memory device according to the third embodiment. A detailed method of forming the contact CPa in the memory device 1A according to the third embodiment will now be described.

In the processing of step S400 shown in FIG. 50, first, a contact hole CPH is formed in a region corresponding to a contact CPa. The contact hole CPH is provided to penetrate the insulating layer 24a. The associated sacrificial member SM is exposed in a bottom portion of the contact hole CPH. Then, as shown in FIG. 58, a semiconductor layer 81 and an oxide film 82 are formed along the inner wall of the contact hole CPH. The semiconductor layer 81 is, for example, polysilicon. The oxide film 82 is, for example, a silicon oxide film.

Next, as shown in FIG. 59, the semiconductor layer 81 and the oxide film 82 in a bottom portion of the contact hole CPH are removed by anisotropic etching processing. Thereby, a part of the semiconductor layer 81 is exposed in the bottom portion of the contact hole CPH.

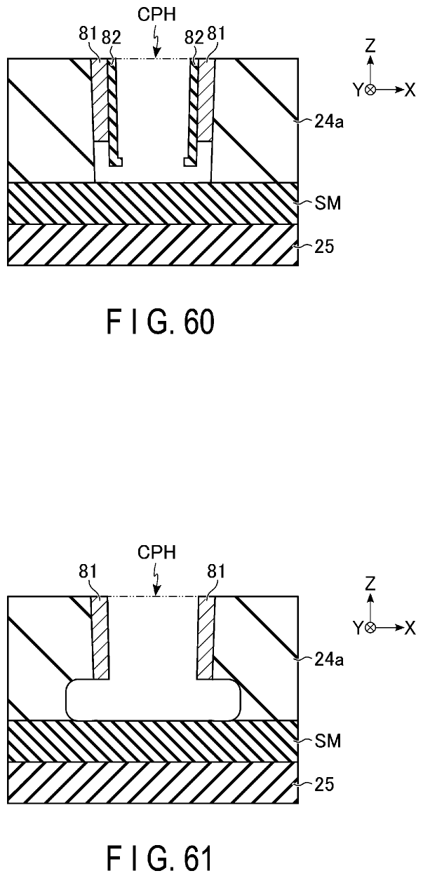

Next, as shown in FIG. 60, a part of the semiconductor layer 81 is selectively removed by, for example, wet etching processing. In this wet etching processing, conditions whereby the etching rate for the semiconductor layer 81 is higher than the etching rate for each of the oxide film 82 and the sacrificial member SM are used. Further, in this wet etching processing, the semiconductor layer 81 is removed via a region between the oxide film 82 and the inner wall of the contact hole CPH. Therefore, the area where the semiconductor layer 81 is removed can be adjusted by controlling the etching time. The area where the semiconductor layer 81 is removed is determined based on the thickness of the wide portion WP.

Next, as shown in FIG. 61, the oxide film 82 and a part of the insulating layer 24a are removed by, for example, wet etching processing. In this wet etching processing, side etching of the insulating layer 24a proceeds from the bottom portion of the contact hole CPH where the semiconductor layer 81 has been removed. Then, a space corresponding to the shape of the wide portion WP is formed in a bottom portion of the contact hole CPH. After that, the semiconductor layer 81 is removed from the inside of the contact hole CPH, and a conductor is embedded; thereby, a contact CPa having a wide portion WP is formed.

### <3-2-3> Detailed Method of Forming the Contact CCa

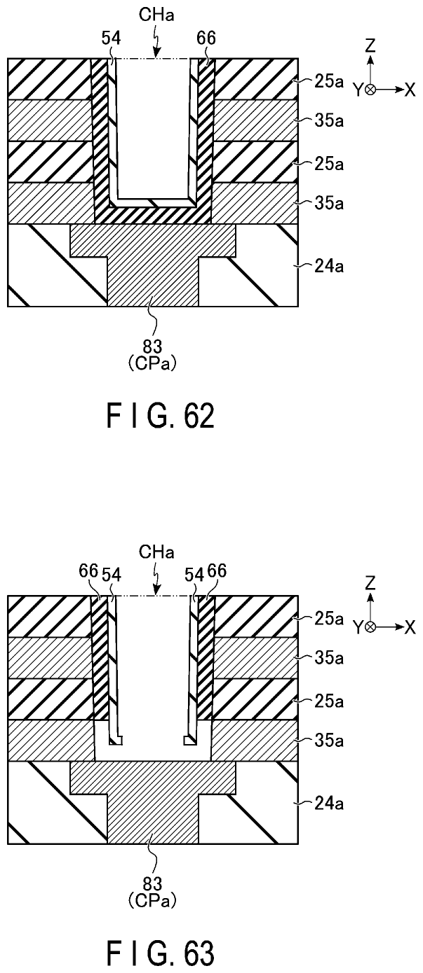

A detailed method of forming the contact CCa in the memory device 1A according to the third embodiment will now be described. Each of FIGS. 62 to 64 is a cross-sectional view showing an example of a detailed cross-sectional structure in the formation process of a contact included in the memory device according to the third embodiment. In the present example, it is assumed that a conductive member 83 is embedded in the contact hole CPH.

If the sacrificial member 67 is removed by the processing of step S404 shown in FIG. 50, a sacrificial film 54 is formed along the insulating film 66 in the contact hole CHa, as shown in FIG. 62. Next, the sacrificial film 54 in a bottom portion of the contact hole CHa is removed by anisotropic etching processing. Thereby, a part of the insulating film 66 is exposed in the bottom portion of the contact hole CHa.

Next, as shown in FIG. 63, a part of the insulating film 66 is selectively removed by, for example, wet etching processing. In this wet etching processing, conditions whereby the etching rate for the insulating film 66 is higher than the etching rate for the sacrificial film 54 are used. Further, in this wet etching processing, the insulating film 66 is removed via a region between the sacrificial film 54 and the inner wall of the contact hole CHa. Therefore, the area where the insulating film 66 is removed can be adjusted by controlling the etching time. Specifically, the area where the insulating film 66 is removed is adjusted such that the conductive layer 35a associated with the contact hole CHa is exposed and the conductive layer 35a adjacent to the associated conductive layer 35a is not exposed.

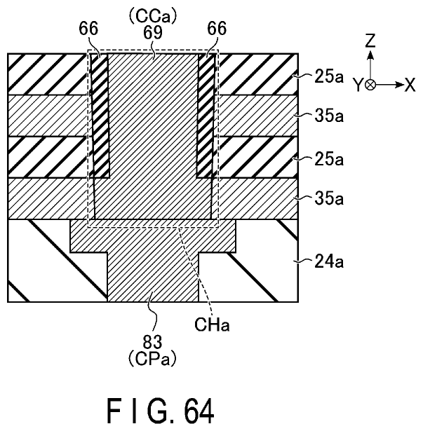

Next, the sacrificial film 54 is removed, and as shown in FIG. 64, a conductive member 69 is embedded in the contact hole CHa. Thereby, the conductive member 69 and the conductive layer 35 come into contact with each other, and are electrically connected to each other. The conductive member 69 in the contact hole CHa functions as a contact CCa. Further, the conductive member 69 in the contact hole CHa and the conductive member 83 in the contact hole CPH are electrically connected to each other. That is, a set of conductive layers 35 associated between the memory layers 200a and 200b can be electrically connected to the semiconductor circuit in the CMOS layer 100 via the contact CPa. The method of manufacturing the other parts of the memory device 1A according to the third embodiment is similar to that of the memory device 1 according to the first embodiment.

### <3-3> Effects of the Third Embodiment

The memory device 1A according to the third embodiment includes a plurality of memory layers 200a and 200b. Conductive layers 35 associated between the memory layers 200a and 200b are electrically connected to each other via a contact CPb connected to a terrace portion of stacked wiring lines of the memory layer 200b from the lower side, and wiring lines associated between the memory layer 200a and the CMOS layer 100 are electrically connected to each other via a contact CPa connected to a terrace portion of stacked wiring lines of the memory layer 200a from the lower side.

Thereby, for example, the arrangement of contacts CPa and CPb connected to word lines WL can be made to overlap in a top view. Then, drawing-around of wiring can be omitted, and word lines WL associated between the memory layers 200a and 200b can be short-circuited. As a result, the memory device 1A according to the third embodiment can reduce the chip area. Therefore, the memory device 1A according to the third embodiment can suppress the manufacturing cost of the memory device 1A.

### <3-4> Modifications of the Third Embodiment

The memory device 1A according to the third embodiment described above can be variously modified. For example, the contact CPa before bonding processing may be configured using a sacrificial member. Further, bonding processing may be executed after replacement processing. In the following, a case where the contact CPa before bonding processing is configured using a sacrificial member is described as a first modification of the third embodiment. Further, a case where bonding processing is executed after replacement processing is described as a second modification of the third embodiment.

### (1: First Modification of the Third Embodiment)

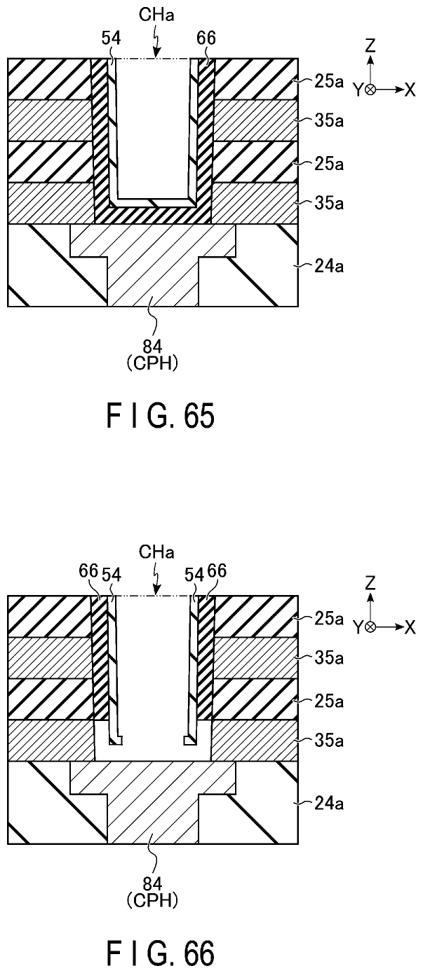

Each of FIGS. 65 to 68 is a cross-sectional view showing an example of a detailed cross-sectional structure in the formation process of the contact CPa included in the memory device 1A according to a first modification of the third embodiment. A detailed method of forming the contact CPa in the memory device 1A according to the first modification of the third embodiment will now be described. In the present example, it is assumed that a sacrificial member 84 is embedded in the contact hole CPH.

If the sacrificial member 67 is removed by the processing of step S404 shown in FIG. 50, a sacrificial film 54 is formed along the insulating film 66 in the contact hole CHa, as shown in FIG. 65. Next, the sacrificial film 54 in a bottom portion of the contact hole CHa is removed by anisotropic etching processing. Thereby, a part of the insulating film 66 is exposed in the bottom portion of the contact hole CHa. Next, as shown in FIG. 66, a part of the insulating film 66 is selectively removed by, for example, wet etching processing like in the third embodiment.

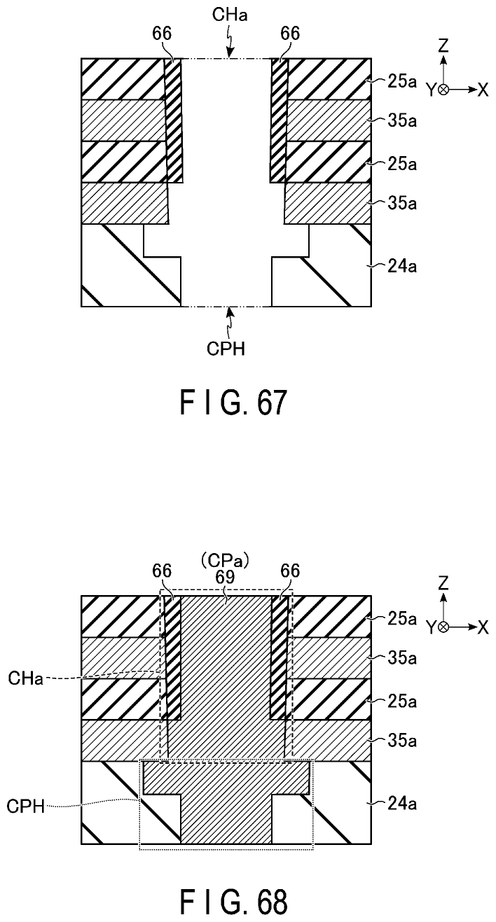

Next, as shown in FIG. 67, the sacrificial film 54 in the contact hole CHa and the sacrificial member 84 in the contact hole CPH are removed. Thereby, a hole in which the contact holes CHa and CPH associated with the same wiring line are connected in the Z direction is formed. Next, as shown in FIG. 68, a conductive member 69 is embedded in the connected contact holes CHa and CPH. Thereby, the conductive member 69 and the conductive layer 35a come into contact with each other, and are electrically connected to each other. In a not-illustrated region, the conductive member 69 formed in the contact hole CPH is connected to the conductive layer 64a.

Thus, in the memory device 1A according to the third embodiment, the contact CPa and the contact CCa may be integrally formed depending on the method of forming the contact CPa.

### (2: Second Modification of the Third Embodiment)

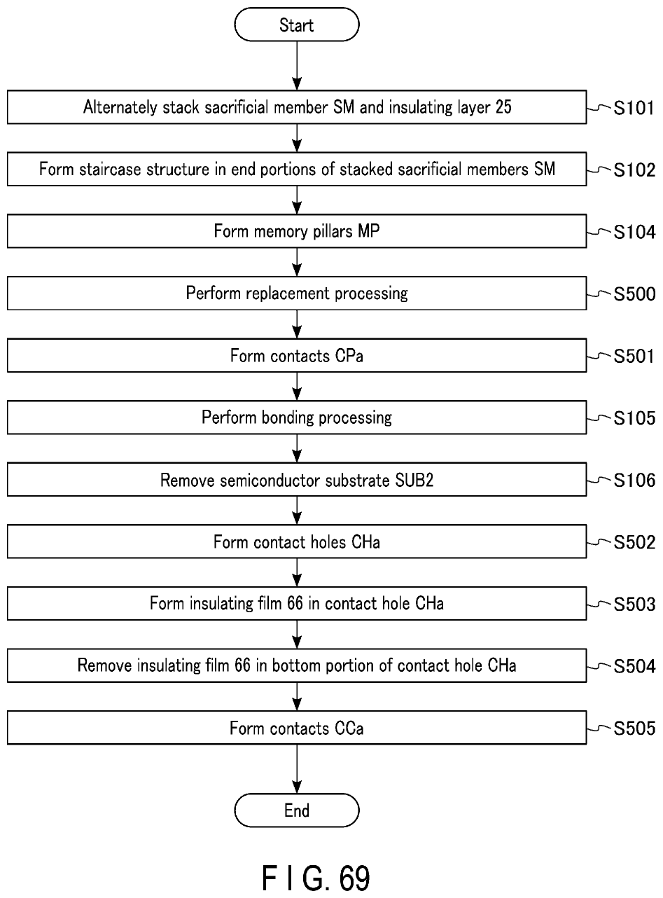

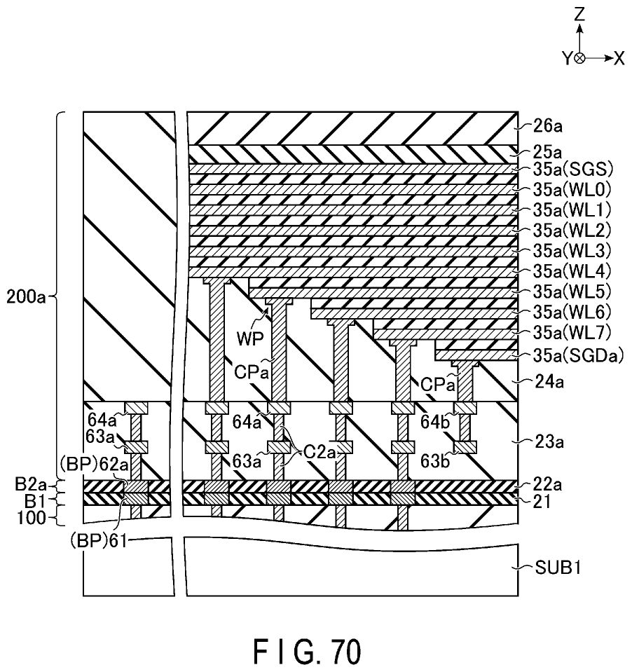

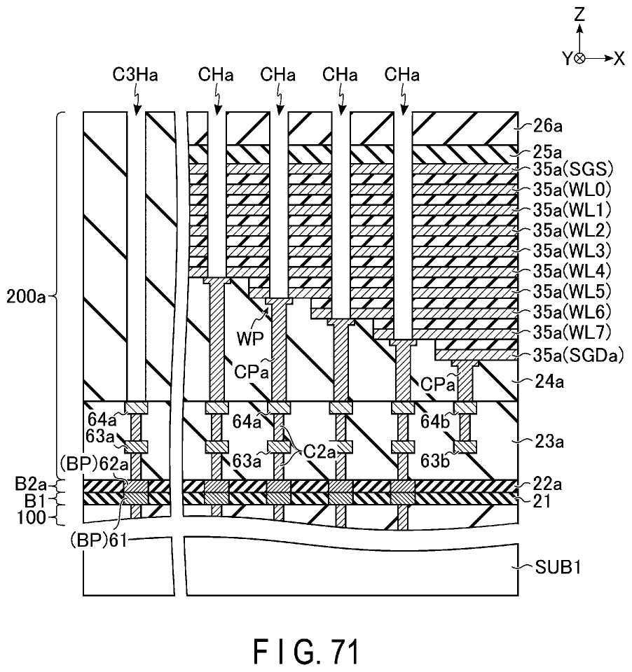

FIG. 69 is a flowchart showing an example of a method of manufacturing the memory device 1A according to a second modification of the third embodiment. Each of FIGS. 70 and 71 is a cross-sectional view showing an example of a cross-sectional structure in the manufacturing process of the memory device 1A according to the second modification of the third embodiment. A method of manufacturing the memory device 1A according to the second modification of the third embodiment will now be described with reference to FIG. 69 as appropriate.

First, like in the third embodiment, a sacrificial member SM and an insulating layer 25 are alternately stacked (step S101). Next, like in the third embodiment, a staircase structure is formed in end portions of the stacked sacrificial members SM (step S102). Next, like in the first embodiment, memory pillars MP are formed (step S104).

Next, replacement processing is executed (step S500). Specifically, slits SLT are formed to divide the stacked sacrificial members SM. Then, the stacked sacrificial members SM are removed via the slit SLT. Then, a conductive layer 35a is formed in the space where the sacrificial member SM has been removed.

Next, contacts CPa are formed (step S501). Each contact CPa is provided to penetrate the insulating layer 24a, and is connected to a terrace portion of the associated conductive layer 35a. A wide portion WP is formed in each contact CPa. Details of the method of forming the wide portion WP are similar to those of the third embodiment.

Next, like in the first embodiment, bonding processing is executed (step S105). Next, like in the first embodiment, the semiconductor substrate SUB2 is removed (step S106). After that, a conductive layer 36 is processed into a desired shape, and as shown in FIG. 70, an insulating layer 26a is formed to cover the conductive layer 36a in a not-illustrated region.

Next, contact holes CHa are formed (step S502). In the processing of step S502, etching processing using the wide portion WP of the contact CPa as an etching stopper is executed. Further, in the processing of step S502, conditions whereby the conductive layer 35a can be etched are used. In the second modification of the third embodiment, each contact hole CHa is provided to penetrate the insulating layers 25a and 26a and at least one conductive layer 35a. As shown in FIG. 71, a part of the associated contact CPa is exposed in a bottom portion of each contact hole CHa. In the processing of step S502, contact holes C3Ha may be simultaneously formed like in the third embodiment.

Next, an insulating film 66 is formed in the contact hole CHa (step S503). Then, the insulating film 66 in a bottom portion of the contact hole CHa is removed (step S504). Then, contacts CCa are formed (step S505). Specifically, the inside of the contact hole CHa is filled with a conductive member 69. Thereby, the conductive member 69 used as a contact CCa and the conductive layer 35a come into contact with each other, and are electrically connected to each other.

Thus, also in a case where replacement processing is executed before bonding processing, a structure similar to that of the memory device 1A described in the third embodiment can be formed.

### <4> Others

The memory devices 1 and 1A described hereinabove can be variously modified.

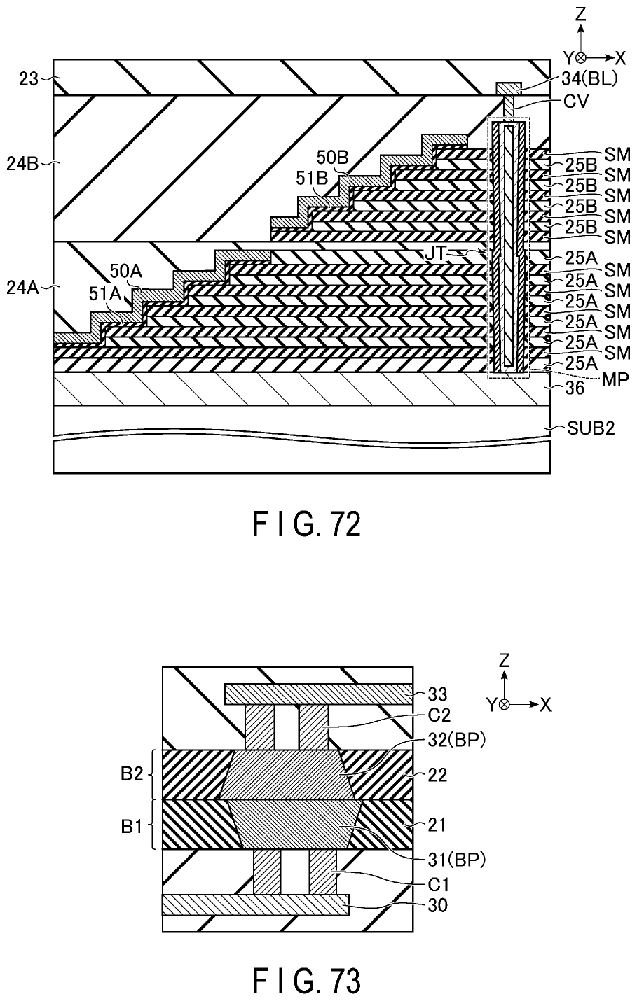

In the first embodiment, the memory pillar MP may have a two-stage structure formed using two memory holes MH coupled in the Z direction. FIG. 72 is a cross-sectional view showing an example of a cross-sectional structure in the manufacturing process of a memory device 1 including a memory pillar MP of a two-stage structure. FIG. 72 shows a state where a structure corresponding to a memory layer 200 is formed on a semiconductor substrate SUB2. As shown in FIG. 72, in the present example, each of a plurality of memory pillars MP has a first portion and a second portion standing side by side in the Z direction, and a joint portion JT of which the side surface is discontinuously provided between the first portion and the second portion. Such a memory pillar MP of a two-stage structure is formed using two memory holes MH coupled in the Z direction. In the memory pillar MP of a two-stage structure, the shape of the side surface is discontinuous in the joint portion JT. That is, the side surface of the second portion of the memory pillar MP is provided discontinuously with an extended portion of the side surface of the first portion of the memory pillar MP. In other words, the joint portion JT of the memory pillar MP formed in a plurality of stages can be specified based on a portion where the shape of the side surface of the memory pillar MP is discontinuous.

In FIG. 72, an insulating layer 25 crossing the memory pillar MP below the joint portion JT is shown as an insulating layer 25A, and an insulating layer 25 crossing the memory pillar MP above the joint portion JT is shown as an insulating layer 25B. In a case where the memory pillar MP of a two-stage structure is formed, the stacked structure of sacrificial members SM and insulating layers 25 is formed separately on the upper side and the lower side of the joint portion JT. An insulating layer 51A and a stopper layer 50A are provided on a staircase structure in end portions of the sacrificial members SM and the insulating layers 25A, and the level differences are filled with an insulating layer 24A. The stopper layer 50A has a portion facing, in the Z direction, a terrace portion of each of a plurality of conductive layers 35 alternately stacked with the insulating layers 25A, and is continuously provided. An insulating layer 51B and a stopper layer 50B are provided on a staircase structure in end portions of the sacrificial members SM and the insulating layers 25B, and the level differences are filled with an insulating layer 24B. The stopper layer 50B has a portion facing, in the Z direction, a terrace portion of each of a plurality of conductive layers 35 alternately stacked with the insulating layers 25B, and is continuously provided. Thus, in a case where a memory pillar MP of a two-stage structure is formed, the stopper layers 50A and 50B are apart from each other with a layer including the joint portion JT as a boundary.

FIG. 73 is a cross-sectional view showing an example of a detailed structure of the vicinity of two bonding pads arranged to face each other. FIG. 73 shows a conductive layer 31 (a bonding pad BP) of a CMOS layer 100, a conductive layer 32 (a bonding pad BP) of a memory layer 200, and some contacts and wiring lines connected to these bonding pads BP. As shown in FIG. 73, the two bonding pads BP arranged to face each other can have different tapered shapes based on the etching direction during formation. Specifically, the conductive layer 31 formed using a semiconductor substrate SUB1 has, for example, am inverse tapered shape. The conductive layer 32 formed using a semiconductor substrate SUB2 has, for example, a tapered shape. One of the two bonding pads BP formed in an inverse tapered shape is vertically inverted and joined by bonding processing. Therefore, the conductive layer 32 formed using the semiconductor substrate SUB2 can be regarded as a tapered shape if it is viewed with the semiconductor substrate SUB1 as a reference after bonding processing. In other words, in the shape of a cross section along the Z direction in a portion where the conductive layer 31 and the conductive layer 32 are joined, the side wall of the portion may not have a straight-lined shape but the portion may forms a non-rectangular shape. Also the shapes of two bonding pads BP arranged to face each other in other portions can be formed in a similar manner to the conductive layers 31 and 32.

Further, a set of two bonding pads BP arranged to face each other can be joined in a shifted manner according to alignment at the time of bonding processing. Therefore, a level difference can be formed between the upper surface of the conductive layer 31 and the lower surface of the conductive layer 32. A set of two bonding pads BP arranged to face each other may have a boundary, or may be integrated. A bonding pad BP and a contact connected to the bonding pad BP may be integrally formed. A plurality of contacts may be connected to a bonding pad BP. For example, the conductive layer 31 may be connected to a conductive layer 30 via a plurality of contacts C1. Similarly, the conductive layer 32 may be connected to a conductive layer 33 via a plurality of contacts C2.

In the above embodiments, each of the circuit configurations, the planar layouts, and the cross-sectional structures of the memory devices 1 and 1A can be changed as appropriate. The memory pillar MP may have a structure in which a pillar corresponding to a select gate line SGD and a pillar corresponding to a word line WL are coupled. The memory pillar MP and a bit line BL may be connected to each other by a plurality of contacts coupled in the Z direction. A conductive layer may be inserted into the coupled portion between contacts. The numbers of wiring layers and contacts included in the memory devices 1 and 1A can be changed according to circuit design as appropriate. The memory pillar MP may have a tapered shape, an inverse tapered shape, or a bowing shape. The slit SLT may have a tapered shape, an inverse tapered shape, or a bowing shape. The XY cross-sectional structure of each of the memory pillar MP and the contacts CC, CCa, CPa, CPb, C1 to C3, C2a, C3a, C2b, C3b, CV, CVa, and CVb may be a circular shape or an elliptical shape.

In the present specification, the bottom portion of each of the contact and the contact hole may include a part of the side surface. The stopper layer 50 may be referred to as a stopper member. Each wiring line in the stacked wiring lines may include a metal oxide film around a conductor such as tungsten. The conductive layer alternately stacked with the insulating layer in the stacked wiring lines may be regarded as a configuration including such a metal oxide film.

The manufacturing processes described in the above embodiments are merely examples. For example, other processing may be inserted between manufacturing steps, and the order of the manufacturing steps may be changed to the extent that no problem occurs. In the present specification, “connection” refers to being electrically connected, and does not exclude, for example, being connected via another element. “Electrically connected” may be connection via an insulator as long as operations similar to those in a case of being electrically connected can be performed. The “tapered shape” refers to a shape that becomes thinner with distance from a member taken as a reference. The “inverse tapered shape” refers to a shape that becomes thicker with distance from a member taken as a reference. “Columnar” refers to a structure provided in a hole formed in the manufacturing process of the memory devices 1 and 1A. The “diameter” refers to the inner diameter of a hole or the outer diameter of a pillar in a cross section (an XY cross section) parallel to a surface of a substrate. The “semiconductor substrate” may be referred to simply as a “substrate”. The “semiconductor layer” may be referred to as a “conductive layer”. The “region” may be regarded as a configuration included by a substrate. For example, in a case where it is provided that a semiconductor substrate SUB1 includes a memory region MR and a hookup region HR, the memory region MR and the hookup region HR are associated with different regions above the semiconductor substrate SUB1. The “height” corresponds to, for example, the spacing in the Z direction between a configuration of a measurement object and the semiconductor substrate SUB1. As a reference of “height”, a configuration other than the semiconductor substrate SUB1 may be used. The “top (planar) view” corresponds to, for example, viewing the front surface of the semiconductor substrate SUB1 from the vertical direction of the semiconductor substrate SUB1.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit.

What is claimed is:

1. A memory device, comprising:
a substrate;
a plurality of first conductive layers provided apart from each other in a first direction above the substrate;
an insulating layer provided above the first conductive layers;
a plurality of pillars, each of the plurality of pillars being provided to extend in the first direction, and the plurality of pillars having portions facing the first conductive layers and functioning as memory cells; and
a plurality of contacts, each of the plurality of contacts being provided to extend in the first direction, and the plurality of contacts being connected to the first conductive layers, respectively, wherein
each of the first conductive layers has, between itself and the substrate, a terrace portion not overlapping with another first conductive layer, and
each of the contacts penetrates the insulating layer and is, in a bottom portion thereof, connected to the terrace portion of one first conductive layer among the first conductive layers.

2. The memory device of claim 1, further comprising:
a stopper member provided to face the terrace portion of each of the first conductive layers in the first direction.

3. The memory device of claim 2, wherein
the stopper member includes a stopper layer provided continuously, and
the stopper layer and each of the contacts are insulated from each other via an oxide film.

4. The memory device of claim 1, further comprising:
an insulating member provided to divide the first conductive layers in a second direction crossing the first direction and having a portion with a staircase shape along the terrace portion of each of the first conductive layers.

5. The memory device of claim 2, wherein
each of the pillars has a first portion and a second portion, the second portion being arranged side by side with the first portion in the first direction, a side surface of the second portion being provided discontinuously with an extended portion of a side surface of the first portion, and
the stopper member includes a first stopper layer provided continuously and a second stopper layer provided continuously, the first stopper layer having a portion facing, in the first direction, the terrace portion of, among the first conductive layers, each of first conductive layers crossing the first portion of the pillar, the second stopper layer having a portion facing, in the first direction, the terrace portion of, among the first conductive layers, each of first conductive layers crossing the second portion of the pillar, and the first stopper layer and the second stopper layer being apart from each other.

6. The memory device of claim 3, further comprising:
an insulating film provided for each of the contacts and provided to surround a part of a side surface of each of the contacts, wherein
each of the contacts has a first portion and a second portion on the first portion, a side surface of the second portion being surrounded by the insulating film, in each of the contacts a side surface of the first portion and a side surface of the insulating film being aligned, and the first portion having a portion facing the one first conductive layer in a direction parallel to a surface of the substrate.

7. The memory device of claim 6, wherein
the first portion of each of the contacts contains polysilicon, and
the second portion of each of the contacts and the one first conductive layer contain a same kind of conductor.

8. The memory device of claim 6, wherein
the first portion and the second portion of each of the contacts, and the one first conductive layer are integrally provided.

9. The memory device of claim 8, wherein
the first portion of at least one of the contacts includes a void.

10. The memory device of claim 2, wherein
in the stopper member, a plurality of portions each facing the terrace portion of each of the first conductive layers are provided apart from each other.

11. The memory device of claim 10, wherein
the contacts include a first contact, and the first contact and a first conductive layer connected to the first contact among the first conductive layers are integrally provided.

12. The memory device of claim 1, further comprising:
a second conductive layer and a third conductive layer provided at heights between the substrate and the first conductive layers, wherein
the one first conductive layer is coupled to a control circuit on the substrate via the second conductive layer and the third conductive layer,
the second conductive layer has an inverse tapered shape, and
the third conductive layer has a tapered shape.

13. The memory device of claim 12, wherein
the one first conductive layer is coupled to the control circuit further via one contact associated with the one first conductive layer among the contacts, a second contact extending in the first direction in a region not overlapping with the first conductive layers in a top view, and a fourth conductive layer provided above the insulating layer and connecting the one contact and the second contact.

14. A memory device, comprising:
a substrate;
a plurality of first conductive layers provided apart from each other in a first direction above the substrate;
a plurality of first pillars each of which is provided to extend in the first direction and of which portions facing the first conductive layers function as first memory cells;
a plurality of first contacts each coupled to a circuit provided between the substrate and the first conductive layers;
a plurality of second contacts individually provided on the first contacts and individually coupled to the first contacts;
a plurality of second conductive layers provided apart from the first conductive layers and apart from each other in the first direction above the first conductive layers;
a plurality of second pillars each of which is provided to extend in the first direction and of which portions facing the second conductive layers function as second memory cells; and
a plurality of third contacts individually coupled to the second conductive layers, wherein
each of the first conductive layers has, between itself and the substrate, a terrace portion not overlapping with another first conductive layer, and
each of the second contacts is, in a bottom portion thereof, connected to the terrace portion of one first conductive layer among the first conductive layers, and connects one first contact among the first contacts and one third contact among the third contacts to each other.

15. The memory device of claim 14, wherein
each of the first contacts has a first portion and a second portion on the first portion, a side surface of the second portion being provided discontinuously with the first portion,
in a boundary portion between the one first contact and each of the second contacts connected to each other, an area of the second portion of the one first contact in a plane parallel to a surface of the substrate is larger than an area of each of the second contacts in a plane parallel to the surface of the substrate, and
in a boundary portion between the first portion and the second portion of the one first contact, an area of the second portion in a plane parallel to the surface of the substrate is larger than an area of the first portion in a plane parallel to the surface of the substrate.

16. The memory device of claim 14, further comprising:
an insulating film provided for each of the second contacts and provided to surround a part of a side surface of each of the second contacts, wherein
each of the second contacts has a first portion and a second portion on the first portion, a side surface of the second portion being surrounded by the insulating film, in each of the second contacts a side surface of the first portion and a side surface of the insulating film being aligned, and the first portion having a portion facing the one first conductive layer in a direction parallel to a surface of the substrate.

17. The memory device of claim 14, wherein
a portion between the one first contact and each of the second contacts connected to each other has a boundary portion.

18. The memory device of claim 14, wherein
the one first contact and each of the second contacts connected to each other are integrally provided.

19. The memory device of claim 14, further comprising:
a third conductive layer and a fourth conductive layer provided at heights between the substrate and the first contacts, wherein
the one first conductive layer is coupled to a control circuit on the substrate via the third conductive layer and the fourth conductive layer,
the third conductive layer has an inverse tapered shape, and
the fourth conductive layer has a tapered shape.

20. The memory device of claim 19, further comprising:
a fifth conductive layer and a sixth conductive layer provided at heights between the second contacts and the third contacts, wherein
one second conductive layer among the second conductive layers is coupled to the one first conductive layer via the fifth conductive layer and the sixth conductive layer,
the fifth conductive layer has an inverse tapered shape, and
the sixth conductive layer has a tapered shape.
